(19) United States
(12) Patent Application Publication
(10) Pub. No.: US 2026/0327816 A1
(43) Pub. Date: Oct. 22, 2026

(54) AN ELECTROLYTIC CELL AND METHOD OF ELECTROLYSIS

(71) Applicant: ROYAL MELBOURNE INSTITUTE OF TECHNOLOGY, Melbourne, Victoria (AU)

(72) Inventors: Amgad Rezk, Melbourne, Victoria (AU); Leslie Yeo, Melbourne, Victoria (AU); Yemima Ehrnst, Melbourne, Victoria (AU)

(21) Appl. No.: 19/105,679

(22) PCT Filed: Aug. 23, 2023
(86) PCT No.: PCT/AU2023/050811

§ 371 Date: Feb. 21, 2025

(30) Foreign Application Priority Data
Aug. 23, 2022 (AU) 2022902403

(51) Int. Cl. C25B 9/13; C25B 1/04; C25B 9/65; C25B 15/00; H10N 30/20; H10N 30/87

(52) U.S. Cl. CPC C25B 9/13; C25B 9/65; C25B 15/00; C25B 1/04; H10N 30/20; H10N 30/87

(57) ABSTRACT

The invention provides an electrolytic cell, comprising: a working electrode; a counter electrode; a liquid electrolyte in contact with a working surface of the working electrode; an acoustically transmissive substrate comprising at least a piezoelectric substrate portion; one or more conductive electrodes coupled to the piezoelectric substrate portion and configured to propagate a high frequency acoustic wave having a frequency of at least 1 MHz across the acoustically transmissive substrate when electrically actuated; and one or more power supplies configured (i) to apply a potential between the working electrode and the counter electrode sufficient to electrolytically react a species in the liquid electrolyte, thereby producing an electrolytic reaction product proximate the working electrode, and (ii) to electrically actuate the one or more conductive electrodes, wherein the working electrode is either located on the acoustically transmissive substrate or spaced apart from the acoustically transmissive substrate by the liquid electrolyte, and wherein propagation of the high frequency acoustic wave across the acoustically transmissive substrate in operation of the electrolytic cell stimulates the liquid electrolyte, thereby increasing the production efficiency of the electrolytic reaction product.

### TECHNICAL FIELD

The invention relates to an electrolytic cell comprising a working electrode in contact with a liquid electrolyte, wherein the working electrode is either located on an acoustically transmissive substrate or spaced apart from an acoustically transmissive substrate by the liquid electrolyte. In operation of the electrolytic cell, a high frequency acoustic wave propagating across the acoustically transmissive substrate stimulates the liquid electrolyte, thereby increasing the production efficiency of an electrolytic reaction product produced proximate the working electrode. The invention further relates to a method of electrolysis and an electrode apparatus for an electrolytic cell. The invention is of particular interest for electrolysis of water to produce hydrogen, and it will be convenient to disclose aspects of the invention in this context. However, the invention is not so limited and encompasses electrolytic cells and methods of electrolysis for a range of electrolytic processes.

### BACKGROUND OF INVENTION

Green hydrogen (H₂) produced by water electrolysis is set to be pivotal in the transition to a clean-energy economy as it can provide a high-energy density carrier for renewable energy, or replace H₂ currently produced from fossil fuel sources. However, electrolysis only accounts for a small percentage of current global hydrogen production, due in part to the low production efficiency stemming from the ohmic losses associated with the kinetic overpotential of electrolysis systems and bubble build-up on the electrodes. Commercial water electrolysis generally uses strongly acidic or alkaline electrolytes and expensive platinum group metal (PGM) electrocatalysts to achieve the lowest onset potentials for the hydrogen evolution reaction (HER). Nevertheless, a high overpotential, typically of multiple volts, is usually required to reach industrially practical current densities (e.g. 200-500 mA cm⁻²). Aside from the energy inefficiency, electrolysis at such high overpotentials is susceptible to operational problems including corrosive acidic fogs in acidic electrolytes and electrocatalyst instability in alkaline electrolytes.

It is therefore desirable to decrease the overpotential required to achieve a target current density, preferably while also utilizing neutral or near-neutral electrolytes and/or non-PGM electrocatalysts. This is particularly challenging since the HER rate is inherently low at neutral pH values due to the rapid consumption of hydronium ions (H₃O⁺) and the consequent need for higher overpotentials to drive the thermodynamically unfavourable reduction of H₂O. This phenomenon can be observed as a “plateau” in the current-voltage response curve in linear sweep voltammetry (LSV) experiments.

A further difficulty with water electrolysis, at any pH value, is the evolution and adhesion of gas bubbles on the electrodes (H₂ on the cathode and O₂ on the anode). The bubbles reduce the effective surface area of the electrode and inhibit mass transfer of ionic species and heat transfer between the bulk electrolyte and the electrocatalyst, thus contributing significantly to the electrolysis overpotential. Furthermore, bubble adhesion and removal can cause rapid erosion of the electroactive surface of the electrode.

Acoustic stimulation using power ultrasound (20-100 kHz acoustic waves) has previously been used in attempts to address these issues. The observed modest reductions in overpotential have been ascribed to various sonoelectrochemical mechanisms attributed, in substantial part, to acoustic cavitation which is induced by bulk ultrasound waves propagating through the electrolyte adjacent to the electrode surface. Accordingly, low frequency and high power ultrasonic stimulation (i.e. power ultrasound) capable of inducing cavitation has been considered necessary to provide meaningful gains. Low frequencies are typically also considered necessary to provide an acceptably high acoustic propagation distance (attenuation length) from the ultrasonicator into the electrolyte.

In one example, international patent application WO2013/003499 discloses acoustic stimulation of the aqueous electrolyte in an electrolytic cell to induce acoustic cavitation in the region between the cathode and anode. Frequencies of 20 kHz to 100 kHz are said to be suitable to cavitate the electrolyte.

However, the use of power ultrasound enhanced electrolysis has a number of significant disadvantages. Firstly, the increase in power density at a given overpotential is somewhat limited and the resultant energy efficiencies are offset by the high power input required to generate the ultrasound itself. Conventional ultrasonicators (e.g. bath and probe sonicators) are bulky and inefficient as the sound waves propagate throughout the liquid media and associated physical equipment so that only a fraction of the applied energy enhances hydrogen production. In neutral electrolytes, the energy balance is expected to be negative, and ultrasonic stimulation has thus generally been proposed only for strongly acidic or alkaline electrolytes. Secondly, acoustic cavitation produced by power ultrasound is highly erosive on the electrode surface, thereby affecting the long-term stability of the electrolysis system. This is of particular concern if the electrode itself is present on the oscillating surface which emits the power ultrasound (i.e. a “sonotrode”), since rapid physical degradation of the electrode can be expected. In addition, ultrasonic devices, especially in the Hz and KHz frequencies, co-produce high audible noise, necessitating ear protection equipment and limiting use in some settings.

The foregoing discussion concerns the electrolytic reactions taking placing at the cathode and anode of water electrolysis cells (i.e. the hydrogen evolution reaction and the oxygen evolution reaction respectively), but it will be appreciated that similar considerations apply to a range of other electrolysis reactions where the performance is limited by undesirably high overpotentials.

There is therefore an ongoing need for new apparatus for electrolytic cells and methods of electrolysis which at least partially address one or more of the above-mentioned short-comings, or provide a useful alternative.

A reference herein to a patent document or other matter which is given as prior art is not to be taken as an admission that the document or matter was known or that the information it contains was part of the common general knowledge as at the priority date of any of the claims.

### SUMMARY OF INVENTION

The inventors have now discovered that very significant enhancements in the hydrogen evolution reaction (HER) rate can be obtained during water electrolysis by stimulating the liquid electrolyte proximate the working surface of the working electrode with acoustic waves having a frequency well above the power ultrasound range previously used in electrolysis reactions. This is achieved by propagating suitably high frequency acoustic waves having a frequency of at least 1 MHz across an acoustically transmissive substrate, with the working electrode either located on that substrate or spaced apart from the substrate by the liquid electrolyte. The high frequency acoustic waves may suitably be generated by electrically actuating one or more conductive electrodes coupled to a piezoelectric portion of the substrate, with the form of the resultant waves, e.g. surface acoustic waves (SAW), surface-reflected bulk waves (SRBW) or Lamb waves, depending on the relative configuration of the electrodes and substrate.

The observed results, showing an improvement in current density at a target overpotential of up to fourteen-fold in neutral electrolytes, are surprising and advantageous because the power input is considerably lower than that required in conventional ultrasonic methods and the acoustic frequencies are too high to induce acoustic cavitation in the electrolyte. Indeed, the results cannot be explained by conventional sonoelectrochemical mechanisms alone and the inventors have obtained evidence of a new effect in which the hydrogen bonding network of water molecules at the electrode-electrolyte interface is disrupted by the high frequency acoustic waves propagating across the electrode surface.

Because of the absence of cavitation and the low power input, physical degradation of the working surface can be avoided or minimised and the energy penalty associated with the acoustic wave generation is reduced compared to the efficiencies obtained in the electrolysis. Advantageously, the methods disclosed herein allow high current densities to be achieved even with neutral electrolytes and non-PGM electrocatalysts.

In accordance with a first aspect the invention provides an electrolytic cell, comprising: a working electrode; a counter electrode; a liquid electrolyte in contact with a working surface of the working electrode; an acoustically transmissive substrate comprising at least a piezoelectric substrate portion; one or more conductive electrodes coupled to the piezoelectric substrate portion and configured to propagate a high frequency acoustic wave having a frequency of at least 1 MHz across the acoustically transmissive substrate when electrically actuated; and one or more power supplies configured (i) to apply a potential between the working electrode and the counter electrode sufficient to electrolytically react a species in the liquid electrolyte, thereby producing an electrolytic reaction product proximate the working electrode, and (ii) to electrically actuate the one or more conductive electrodes, wherein the working electrode is either located on the acoustically transmissive substrate or spaced apart from the acoustically transmissive substrate by the liquid electrolyte, and wherein propagation of the high frequency acoustic wave across the acoustically transmissive substrate in operation of the electrolytic cell stimulates the liquid electrolyte, thereby increasing the production efficiency of the electrolytic reaction product.

In some embodiments, the working electrode is located on the acoustically transmissive substrate. In some such embodiments, the working electrode is located on the piezoelectric substrate portion.

In some embodiments, the working electrode is spaced apart from the acoustically transmissive substrate by a distance through the liquid electrolyte of no more than 30 mm, or no more than 20 mm, or no more than 10 mm, such as about 5 mm or less.

In some embodiments, the high frequency acoustic wave has a frequency of greater than 1 MHz, for example at least 1.5 MHz, or at least 2 MHz, or at least 3 MHz, or at least 5 MHz.

In some embodiments, the high frequency acoustic wave comprises a wave form selected from the group consisting of a surface acoustic wave (SAW), a surface reflected bulk wave (SRBW) and a Lamb wave. In some embodiments, the wave form is selected from the group consisting of a SAW or a SRBW.

In some embodiments, h/λ is greater than ⅓, or greater than ½, or greater than 1, where h is the thickness of the piezoelectric substrate portion and A is the acoustic wavelength of the high frequency acoustic wave when propagating across the piezoelectric substrate portion.

In some embodiments, h/λ is between ⅓ and 3, or between ½ and 3, or between 1 and 2, where h is the thickness of the piezoelectric substrate portion and A is the acoustic wavelength of the high frequency acoustic wave when propagating across the piezoelectric substrate portion.

In some embodiments, the power input required to actuate the one or more conductive electrodes, normalised to the surface area of the acoustically transmissive substrate, is less than 20 W/cm², or less than 10 W/cm², or less than 5 W/cm², or less than 1 W/cm².

In some embodiments, the working electrode comprises an electrocatalyst for the hydrogen evolution reaction at the working surface.

In some embodiments, the working electrode comprises one or more layers of a metallic composition or a metal compound formed on a surface of the acoustically transmissive substrate. The working electrode may comprise a layer at the working surface comprising at least one selected from the group consisting of gold, platinum, titanium, titanium dioxide, molybdenum disulphide, graphene, and aluminium.

In some embodiments, the piezoelectric substrate portion is configured as a plate and the high frequency acoustic wave propagates in the plane of the plate, thereby oscillating at least one surface of the plate.

In some embodiments, the piezoelectric substrate portion comprises a single crystal selected from the group consisting of lithium niobate, quartz, lithium tantalate, and lanthanum gallium silicate.

In some embodiments, the one or more conductive electrodes comprises a pair of separated electrodes. The pair of separated electrodes may be a pair of interdigitated electrodes. The pair of conductive electrodes may be patterned on a surface of the piezoelectric substrate portion.

In some embodiments, the liquid electrolyte is an aqueous electrolyte. In some such embodiments, the aqueous electrolyte has a pH of between 5 and 9.

In some embodiments, the electrolytic reaction product is hydrogen (H₂) or oxygen (O₂).

In some embodiments, the electrolytic cell is configured to flow the liquid electrolyte past the working electrode.

In some embodiments, the electrolytic cell comprises an ion-permeable membrane which separates the working electrode and the counter electrode. Optionally, the electrolytic cell comprises a second liquid electrolyte in contact with the counter electrode. The ion-permeable membrane may prevent bulk mixing of the liquid electrolyte in contact with the working surface of the working electrode and the second liquid electrolyte. Optionally, the electrolytic cell is configured to flow the second liquid electrolyte past the counter electrode.

In some embodiments, the electrolytic cell is a cell for water electrolysis. liquid electrolyte will thus be an aqueous electrolyte, and in some embodiments a neutral aqueous electrolyte (pH 5-9). The working electrode may be the cathode or the anode, preferably the cathode. The cell for water electrolysis may be configured to flow the liquid electrolyte past the working electrode. The cathode may comprise an electrocatalyst for the hydrogen evolution reaction at the working surface. The anode may comprise an electrocatalyst for the oxygen evolution reaction.

Optionally, the working electrode is the cathode and the electrolytic cell is further configured to stimulate liquid electrolyte in contact with the anode by propagation of a high frequency acoustic wave across an acoustically transmissive substrate, typically a second acoustically transmissive substrate. The anode may be located on the acoustically transmissive substrate or spaced apart from the acoustically transmissive substrate by liquid electrolyte. The cell for water electrolysis may optionally include a proton-permeable membrane which separates the cathode and the anode. Optionally, the cell is configured to flow an aqueous catholyte past the cathode and an aqueous anolyte past the anode, with the proton-permeable membrane preventing bulk mixing of the catholyte and anolyte.

In accordance with a second aspect the invention provides a method of electrolysis, comprising: contacting a liquid electrolyte with a working surface of a working electrode; propagating a high frequency acoustic wave having a frequency of at least 1 MHz across an acoustically transmissive substrate, wherein the working electrode is either located on the acoustically transmissive substrate or spaced apart from the acoustically transmissive substrate by the liquid electrolyte; and applying a potential between the working electrode and a counter electrode sufficient to electrolytically react a species in the liquid electrolyte, thereby producing an electrolytic reaction product proximate the working electrode, wherein propagation of the high frequency acoustic wave across the acoustically transmissive substrate stimulates the liquid electrolyte, thereby increasing the production efficiency of the electrolytic reaction product.

The frequency of the high frequency acoustic wave which propagates across the acoustically transmissive substrate is too high to induce cavitation in the liquid electrolyte. Thus, the liquid electrolyte is stimulated without inducing cavitation therein.

In some embodiments, the working electrode is located on the acoustically transmissive substrate.

In some embodiments, the working electrode is spaced apart from the acoustically transmissive substrate by a distance through the liquid electrolyte of no more than 100 mm, or no more than 30 mm, or no more than 20 mm, or no more than 10 mm, such as about 5 mm or less.

In some embodiments, the electrolytic reaction product is hydrogen (H₂) or oxygen (O₂).

In some embodiments, the electrolytic reaction product is H₂ and the potential at the working electrode is no greater than (more negative than) −2.5V vs RHE, or no greater than (more negative than) −1.5V vs RHE, or no greater than (more negative than) −1.0V vs RHE.

In some embodiments, the liquid electrolyte is an aqueous electrolyte having a pH of between 5 and 9.

In some embodiments, the high frequency acoustic wave has a frequency of greater than 1 MHz, such as at least 1.5 MHz, or at least 2 MHz, or at least 3 MHz, such as at least 5 MHz.

In some embodiments, the high frequency acoustic wave comprises a wave form selected from the group consisting of a surface acoustic wave (SAW), a surface reflected bulk wave (SRBW) and a Lamb wave. In some embodiments, the wave form is selected from the group consisting of a SAW or a SRBW.

In some embodiments, the power input to propagate the high frequency acoustic wave across the acoustically transmissive substrate, normalised to the surface area of the acoustically transmissive substrate, is less than 20 W/cm², or less than 10 W/cm², or less than 5 W/cm², such as less than 1 W/cm².

In some embodiments, propagating the high frequency acoustic wave across the acoustically transmissive substrate comprises electrically actuating one or more conductive electrodes coupled to a piezoelectric substrate portion of the acoustically transmissive substrate.

In some such embodiments, the one or more conductive electrodes comprises a pair of separated electrodes. The pair of separated electrodes may be a pair of interdigitated electrodes. The pair of conductive electrodes may be patterned on a surface of the piezoelectric substrate portion.

In some embodiments, h/λ is greater than ⅓, or greater than ½, or greater than 1, where h is the thickness of the piezoelectric substrate portion and A is the acoustic wavelength of the high frequency acoustic wave when propagating across the piezoelectric substrate portion.

In some embodiments, h/λ is between ⅓ and 3, or between ½ and 3, or between 1 and 2, where h is the thickness of the piezoelectric substrate portion and A is the acoustic wavelength of the high frequency acoustic wave when propagating across the piezoelectric substrate portion.

In some embodiments, the working electrode is located on the piezoelectric substrate portion.

In some embodiments, the piezoelectric substrate portion comprises a single crystal selected from the group consisting of lithium niobate, quartz, lithium tantalate, and lanthanum gallium silicate.

In some embodiments, the piezoelectric substrate portion is configured as a plate and the high frequency acoustic wave propagates in the plane of the plate, thereby oscillating at least one surface of the plate.

In some embodiments, the working electrode comprises an electrocatalyst for the hydrogen evolution reaction at the working surface.

In some embodiments, the working electrode comprises one or more layers of a metallic composition or a metal compound formed on a surface of the acoustically transmissive substrate, preferably comprising a layer at the working surface comprising at least one selected from the group consisting of gold, platinum, titanium, titanium dioxide, molybdenum disulphide, graphene, and aluminium.

In accordance with a third aspect the invention provides an electrode apparatus for an electrolytic cell, the electrode apparatus comprising: an acoustically transmissive substrate comprising at least a piezoelectric substrate portion; a working electrode located on the acoustically transmissive substrate, the working electrode comprising a working surface for contact with a liquid electrolyte in an electrolytic cell; and one or more conductive electrodes coupled to the piezoelectric substrate portion and configured to propagate a high frequency acoustic wave having a frequency of at least 1 MHz across the acoustically transmissive substrate when electrically actuated.

It will be appreciated that various embodiments of the third aspect may include features as defined herein in the context of the first aspect.

Unless the context requires otherwise, where the terms “comprise”, “comprises” and “comprising” are used in the specification (including the claims) they are to be interpreted as specifying the stated features, integers, steps or components, but not precluding the presence of one or more other features, integers, steps or components, or group thereof.

As used herein, the terms “first”, “second”, “third” etc in relation to various features of the disclosed devices are arbitrarily assigned and are merely intended to differentiate between two or more such features that the device may incorporate in various embodiments. The terms do not of themselves indicate any particular orientation or sequence. Moreover, it is to be understood that the presence of a “first” feature does not imply that a “second” feature is present, the presence of a “second” feature does not imply that a “first” feature is present, etc.

Further aspects of the invention appear below in the detailed description of the invention.

### BRIEF DESCRIPTION OF DRAWINGS

Embodiments of the invention will herein be illustrated by way of example only with reference to the accompanying drawings in which:

FIG. 1 schematically depicts an electrolytic cell according to embodiments of the invention, and as produced in Example 2, in which the working electrode is on the piezoelectric substrate portion of the acoustically transmissive substrate. Insets 120 and 122 depict laser Doppler vibrometry scans of the acoustic waves propagated across the substrate, as measured in Example 3.

FIG. 2 schematically depicts an electrolytic cell according to embodiments of the invention, in which the working electrode is on the piezoelectric substrate portion of the acoustically transmissive substrate.

FIG. 3 schematically depicts an electrolytic cell according to embodiments of the invention, in which the working electrode is spaced apart from the acoustically transmissive substrate by the liquid electrolyte.

FIG. 4 schematically depicts an electrolytic cell according to embodiments of the invention, configured as a flow cell for water electrolysis, in which the working electrode and the counter electrode are each located on a piezoelectric substrate.

FIG. 5 schematically depicts the generation and propagation of a high frequency acoustic wave across an acoustically transmissive substrate in embodiments where the conductive electrodes and the working electrode are both located on the piezoelectric substrate portion of the acoustically transmissive substrate.

FIG. 6 schematically depicts the generation and propagation of a high frequency acoustic wave across an acoustically transmissive substrate in an embodiment where the working electrode is located on the acoustically transmissive substrate, but not on the piezoelectric substrate portion thereof.

FIG. 7 schematically depicts the generation and propagation of a high frequency acoustic wave across an acoustically transmissive substrate in an embodiment where the working electrode is located on the acoustically transmissive substrate and above the conductive electrodes, with a dielectric layer interposed between the piezoelectric substrate portion and the working electrode.

FIG. 8 schematically depicts in plane view (A) and side view (B) the generation and propagation of a high frequency acoustic wave across a piezoelectric substrate when the high frequency acoustic wave is generated by a rectangular IDT.

FIG. 9 schematically depicts the generation and propagation of a high frequency acoustic wave across an acoustically transmissive substrate in embodiments where the working electrode is spaced apart from the acoustically transmissive substrate by the liquid electrolyte.

FIG. 10 schematically depicts the electrolytic cell as produced in Example 2, showing relevant dimensions.

FIG. 11 shows linear sweep voltammograms (LSV) obtained with an electrolytic cell according to an embodiment of the invention, containing a neutral aqueous electrolyte, under silent conditions and when acoustically stimulated at varying power levels (10 dBm, 15 dBm, 20 dBm), as obtained in Example 5.

FIG. 12 is a LSV showing a magnification of the low current density region of FIG. 11.

FIG. 13 is a graph which shows the effect of acoustic stimulation in reducing the overpotential required to achieve two different current densities in the LSV's of FIG. 11.

FIG. 14 depicts a time series of photographs of large bubbles of H₂ growing on and detaching from the working electrode under silent electrolytic conditions, as observed in Example 6.

FIG. 15 depicts a time series of photographs of small bubbles of H₂ detaching from the working electrode under acoustically stimulated electrolytic conditions (20 dBm), as observed in Example 6.

FIG. 16 is a graph showing the overpotential required to maintain a current density of −100 mA cm⁻² over 6 hours, under silent conditions and when acoustically stimulated (15 dBm), in chronopotentiometric electrolysis experiments conducted in Example 7.

FIG. 17 depicts the Raman spectrum of the aqueous electrolyte near the electrode-electrolyte interface when conducting chronopotentiometric electrolysis experiments under silent conditions in Example 8. The spectrum is fitted with 5 Gaussian peaks at set wavelengths, with the lower wavenumbers being associated with water molecules that are strongly bound by hydrogen-bonding interactions within a tetrahedral network structure and the higher wavenumbers being associated with water molecules that are only weakly bound (“frustrated water”).

FIG. 18 depicts the Raman spectrum of the aqueous electrolyte near the electrode-electrolyte interface when conducting chronopotentiometric electrolysis experiments under acoustically stimulated (15 dBm) conditions in Example 8.

FIG. 19 is a graph showing the relative peaks areas of the five Gaussian peaks fitted to the Raman spectra of FIGS. 17 and 18, showing the increase in weakly bound water under acoustic stimulation.

FIG. 20 shows LSVs obtained with an electrolytic cell according to an embodiment of the invention, containing neutral, acidic and alkaline aqueous electrolytes, under silent conditions and when acoustically stimulated (20 dBm), as obtained in Example 9.

FIG. 21 shows LSVs obtained with an electrolytic cell according to an embodiment of the invention where the working electrode is spaced apart from the acoustically transmissive substrate by the liquid electrolyte, under silent conditions and when acoustically stimulated (20 dBm), as obtained in Example 10.

FIG. 22 shows LSVs obtained with an electrolytic cell according to an embodiment of the invention where the working electrode is a nickel anode for the OER, spaced apart from the acoustically transmissive substrate by an alkaline electrolyte, under silent conditions and when acoustically stimulated, as obtained in Example 11.

FIG. 23 shows LSVs obtained with an electrolytic cell according to an embodiment of the invention where the working electrode is a stainless steel anode for the OER, spaced apart from the acoustically transmissive substrate by a neutral electrolyte, under silent conditions and when acoustically stimulated, as obtained in Example 11.

FIG. 24 schematically depicts an electrolytic cell according to embodiments of the invention, configured as a flow cell for water electrolysis, in which the cathode and anode are spaced apart from piezoelectric transducers (to enhance the HER and OER), and separated by a proton-permeable membrane.

FIG. 25 schematically depicts an electrolytic cell according to embodiments of the invention, configured as a flow cell for water electrolysis, in which the cathode and anode are formed on piezoelectric transducers (to enhance the HER and OER), and separated by a proton-permeable membrane.

FIG. 26 depicts a perspective view of a flow cell for electrolysis of water, as described and used in Example 12.

FIG. 27 depicts a side view of the flow cell depicted in FIG. 26.

FIG. 28 depicts the anode of the flow cell depicted in FIG. 26.

FIG. 29 shows linear sweep voltammograms (LSV) obtained under (a) silent conditions and (b) under acoustic stimulation at 40 dBm (7 MHz) during water electrolysis in a flow cell, as described in Example 12.

### DETAILED DESCRIPTION

The present invention relates to an electrolytic cell. The cell comprises a working electrode, a counter electrode and a liquid electrolyte in contact with a working surface of at least the working electrode. The cell further comprises an acoustically transmissive substrate which comprises, or consists of, a piezoelectric substrate portion and one or more, such as two, conductive electrodes coupled to the piezoelectric substrate portion. The conductive electrodes are configured to propagate a high frequency acoustic wave having a frequency of at least 1 MHz across the acoustically transmissive substrate when electrically actuated, for example with an alternating current signal. The cell further comprises one or more power supplies configured (i) to apply a potential between the working electrode and the counter electrode sufficient to electrolytically react a species in the liquid electrolyte, thereby producing an electrolytic reaction product proximate the working electrode, and (ii) to electrically actuate the one or more conductive electrodes. The working electrode is either located on the acoustically transmissive substrate or spaced apart from the acoustically transmissive substrate by the liquid electrolyte, i.e. the liquid electrolyte is arranged between and in contact with both the acoustically transmissive substrate and the working electrode.

In operation of the electrolytic cell, propagation of the high frequency acoustic wave across the acoustically transmissive substrate stimulates the liquid electrolyte, typically proximate the working surface of the working electrode. The effect of this is to increase the production efficiency of the electrolytic reaction product. As used herein, the production efficiency refers to the energy efficiency of producing the electrolytic reaction product in the electrolytic cell. An improved production efficiency may be observed as an increased rate of formation of the electrolytic reaction product at a given potential and/or a reduced potential required to achieve a given production rate. In either case, the improvement may be observed in comparison with the efficiency obtained when operating the cell in an otherwise similar manner but without propagation of the high frequency acoustic wave across the acoustically transmissive substrate.

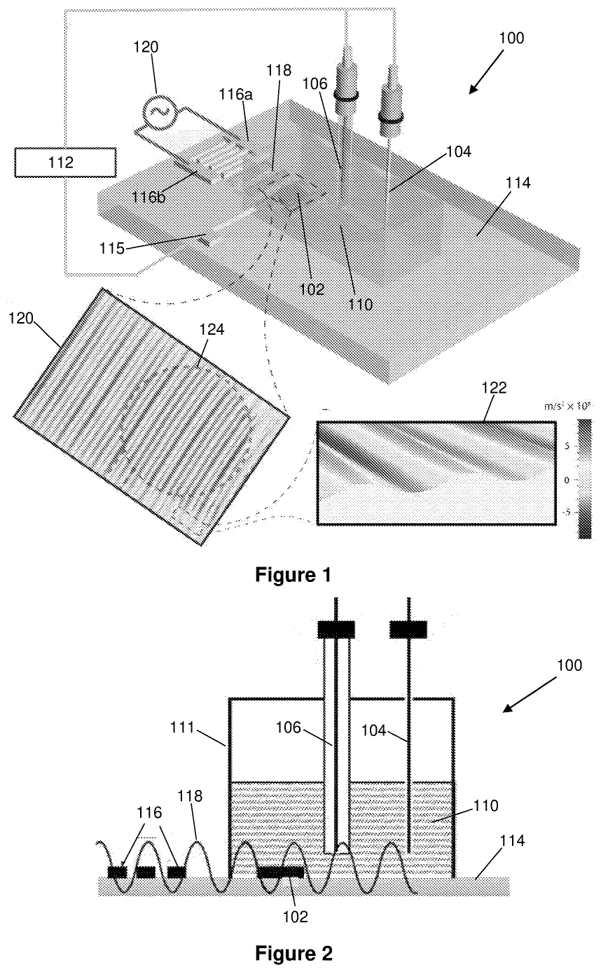

An electrolytic cell 100 according to embodiments of the invention will be described with reference to FIGS. 1 and 2. Cell 100 comprises working electrode 102, counter electrode 104 and optional reference electrode 106, each in contact with liquid electrolyte 110. Cell walls 111 are omitted from FIG. 1 for clarity. The electrodes are connected to power source 112, which is configured to apply a potential between working electrode 102 and counter electrode 104 sufficient to electrolytically react a species in the liquid electrolyte and thus produce an electrolytic reaction product proximate working electrode 102. Working electrode 102 may be a cathode for the hydrogen evolution reaction (HER), so that the electrolytic reaction product comprises H₂. In this case, liquid electrolyte 110 may be an aqueous electrolyte of any pH, including an acidic pH, a neutral pH (pH 5-9) or an alkaline pH. Alternatively, working electrode 102 could be an anode for the oxygen evolution reaction (OER), thus producing O₂ as the electrolytic reaction product, or indeed a cathode or anode for any other desired electrolytic half-reaction.

Working electrode 102 is located on piezoelectric substrate 114, which may suitably be a single crystal of lithium niobate or other piezoelectric material and is preferably in the form of a thin plate, such as in the range of 0.1 to 5 mm thickness. The composition of the working electrode may depend on the desired electrolytic reaction. The working electrode may comprise a metallic composition or metal compound, for example an HER electrocatalyst, at least at the working surface in contact with liquid electrolyte 110. Working electrode 102 may optionally be connected to power source 112 via conductive contact track 115, formed from the same material as the electrode itself.

Electrically conductive electrodes 116, for example interdigitated electrodes 116a and 116b as schematically depicted in FIG. 1, are also located on the surface of piezoelectric substrate 114. The conductive electrodes are configured to propagate a high frequency acoustic wave 118, having a frequency of at least (or greater than) 1 MHz, across substrate 114 when electrically actuated with power source 120, for example a radio frequency (RF) power source. Working electrode 102 is positioned in the wave propagation pathway. The acoustic waves, which may have a frequency of at least 1.5 MHz, or at least 2 MHz, or at least 3 MHz, such as at least 5 MHz, may be observed by known techniques such as laser Doppler vibrometry. An example of this can be seen in laser vibrometry surface scans 120 and 122, depicted as close-up insets in FIG. 1, where dotted circle 124 denotes the outline of working electrode 102 (see Example 3 for further details). The form of the acoustic waves, for example surface acoustic waves (SAW), surface-reflected bulk waves (SRBW) or Lamb waves (a form of bulk waves propagating in a solid substrate), will depend on the configuration of electrodes 116 and the dimensions of substrate 114, as will be described in greater detail hereafter. In all cases, however, the propagated wave causes high frequency oscillations of the surface of piezoelectric substrate 114 which stimulate the working surface of working electrode 102 and the adjacent liquid electrolyte 110. The effect of this, in operation of cell 100, is to increase the production rate of the electrolytic reaction product and/or to reduce the potential required to achieve a target production rate.

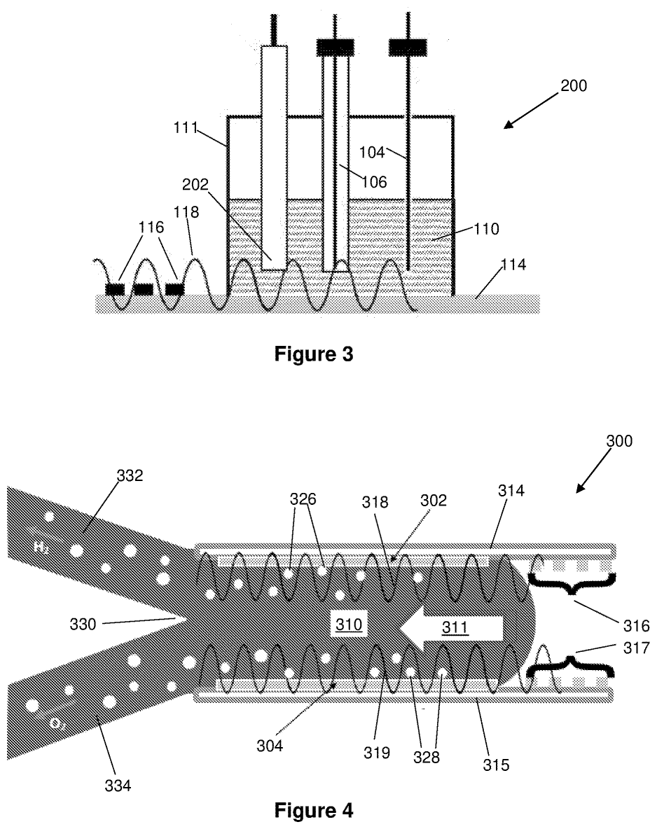

An electrolytic cell 200 according to embodiments of the invention will be described with reference to FIG. 3, in which similarly numbered items are the same as in cell 100. In cell 200, however, working electrode 202 is not located on piezoelectric substrate 114 but is instead spaced apart from piezoelectric substrate 114 by liquid electrolyte 110, with the electrolyte thus arranged between and in contact with the surface of substrate 114 and the working surface of working electrode 202. The spacing distance is preferably small, thus maximising the effect of the acoustic stimulation on the electrolysis reaction taking place proximate the working surface of the working electrode. Working electrode 202 may thus be spaced apart from piezoelectric substrate 114 by a distance of no more than 30 mm, or no more than 20 mm, or nor more than 10 mm, such as above 5 mm or less.

In operation of cell 200, high frequency acoustic wave 118 propagating across piezoelectric substrate 114 oscillates the surface of piezoelectric substrate 114, stimulating the adjacent liquid electrolyte 110. The effect of this is to increase the production rate of the electrolytic reaction product formed proximate working electrode 202 and/or to reduce the potential required to achieve a target production rate.

An electrolytic cell 300 according to embodiments of the invention will be described with reference to FIG. 4. Unless otherwise stated, features of cell 300 are similar to the equivalent features of cell 100. Cell 300 is a flow cell for water electrolysis, comprising cathode 302 and anode 304, each in contact with aqueous electrolyte 310 of any suitable pH, such as an acidic pH, a neutral pH (pH 5-9) or an alkaline pH. Cathode 302 and anode 304 may comprise electrocatalysts suitable to promote the HER and OER respectively. The electrodes are connected to a power source (not shown) configured to apply a potential sufficient to induce electrolysis.

When cell 300 is operated, H₂ bubbles 326 form on cathode 302 and O₂ bubbles 328 form on anode 304 as electrolyte 310 is flowed through the cell in the direction shown by arrow 311. Once past the electrodes, the flowing electrolyte is split at junction 330 into flow streams 332 and 334. When the H₂ and O₂ bubbles detach from their respective electrodes, they are carried downstream in aqueous electrolyte 310. Provided that turbulence in the flowing electrolyte is sufficiently minimised, H₂ bubbles 326 and O₂ bubbles 328 are selectively directed into flow streams 332 and 334 respectively, thus avoiding or reducing the amount of intermixing between the two gaseous electrolysis products. Alternatively, a membrane (not shown) may be interposed between cathode 302 and anode 304 to prevent gas mixing.

Cathode 302 and anode 304 are located on piezoelectric substrates 314 and 315 respectively. Electrically conductive electrode pairs 316 and 317, for example interdigitated electrode pairs, are also located on the surfaces of piezoelectric substrates 314, 315. The electrode pairs are configured to propagate high frequency acoustic waves 318 and 319, each having a frequency of at least (or greater than) 1 MHz, across their respective substrates 314 and 315 when electrically actuated with a suitable power source. Cathode 302 is positioned in the wave propagation pathway of acoustic wave 318 and anode 304 is positioned in the wave propagation pathway of acoustic wave 319. Each acoustic wave may independently have a frequency of at least 1.5 MHz, or at least 2 MHz, or at least 3 MHz, such as at least 5 MHz, with the form of the acoustic waves depending on the configuration of electrodes and the dimensions of the substrates 314, 315. The propagated wave causes high frequency oscillations of the surface of piezoelectric substrates 314, 315, thus stimulating the working surfaces of the electrodes 302, 304 and adjacent liquid electrolyte 310. The effect of this, in operation of cell 300, is to increase the rate of water hydrolysis and/or to reduce the potential required to achieve a target rate of water electrolysis.

The use of acoustic stimulation in this manner facilitates both half-reactions (HER, OER) of the water electrolysis, at least by assisting with bubble detachment at cathode 302 and anode 304. It will, be appreciated, however, that cell 300 could alternatively be configured for acoustic wave propagation only proximate to cathode 302 or only proximate to anode 304.

### High Frequency Acoustic Wave Generation and Propagation

The electrolytic cell according to the present disclosure comprises an acoustically transmissive substrate comprising at least a piezoelectric substrate portion and one or more conductive electrodes coupled to the piezoelectric substrate portion. The conductive electrodes, together with the piezoelectric substrate portion, are configured to propagate a high frequency acoustic wave across the acoustically transmissive substrate when electrically actuated. The conductive electrodes and piezoelectric substrate portion together form a piezoelectric transducer for converting an electric signal into acoustic waves which are transmitted across the substrate. The high frequency acoustic wave is propagated along the surface of the piezoelectric substrate portion, thus oscillating the surface. In embodiments where the piezoelectric substrate portion is configured as a plate, the high frequency acoustic wave may be propagated in the plane of the plate.

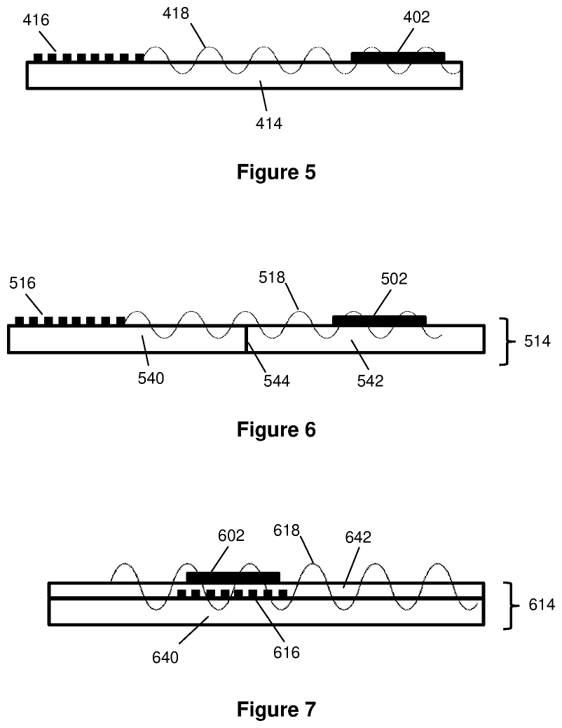

The acoustically transmissive substrate may consist of the piezoelectric substrate portion. For example, FIG. 5 depicts piezoelectric substrate 414 with both the conductive electrodes (e.g. IDT electrodes) 416 and the working electrode 402 located on the surface thereof. When electrically actuated, a high frequency acoustic wave 418 propagates across the piezoelectric substrate to stimulate working electrode 402.

However, it is also contemplated that the acoustically transmissive substrate may comprise other, non-piezoelectric, portions through which the high frequency acoustic wave may propagate. For example, FIG. 6 depicts acoustically transmissive substrate 514 comprising piezoelectric substrate portion 540 and a second, optionally non-piezoelectric, substrate portion 542 (e.g. glass, silicon) adjoining portion 540 at boundary 544. Conductive electrodes (e.g. IDT electrodes) 516 are located on piezoelectric substrate portion 540 while working electrode 502 is located on second substrate portion 542. In use, high frequency acoustic wave 518 is generated on piezoelectric substrate portion 540 but propagates across boundary 544 and second substrate portion 542 to stimulate working electrode 502.

As another example, FIG. 7 depicts acoustically transmissive substrate 614 comprising piezoelectric substrate portion 640 on which conductive electrodes (e.g. IDT electrodes) 616 are located. A thin overlayer 642 of dielectric, acoustically transmissive material is interposed between piezoelectric substrate portion 640 and working electrode 602, to electrically isolate the functional components. In use, high frequency acoustic wave 618 is generated on piezoelectric substrate portion 640 but propagates through acoustically transmissive substrate 614 to stimulate working electrode 602 at its surface.

The piezoelectric substrate portion may be any suitable single crystal or polycrystalline piezoelectric material in which high frequency acoustic waves can be generated. In some embodiments, it is a single crystal piezoelectric material. Single crystals are expected to produce a more well-defined acoustic waveform. A range of suitable piezoelectric materials are known from their applications in acoustic transducers for electronic and telecommunication devices such as filters, oscillators and transformers. In some embodiments, the piezoelectric substrate portion comprises a single crystal selected from the group consisting of lithium niobate, quartz, lithium tantalate, and lanthanum gallium silicate.

The piezoelectric substrate portion may be configured as a plate (or “chip”). The piezoelectric substrate portion is preferably thin, such as in the range of 0.1 to 5 mm thickness or 0.1 to 1 mm thickness. The thickness has an effect on the form of the high frequency acoustic waves generated on the piezoelectric substrate portion and propagated through the acoustically transmissive substrate, as will be explained hereafter.

The one or more conductive electrodes coupled to the piezoelectric substrate portion are typically formed on the surface of the piezoelectric substrate portion. The conductive electrodes may be formed in a desired pattern by deposition of one or more conductive compositions, e.g. a metallic composition, on the piezoelectric substrate surface in one or more deposition layers, by known techniques such as photolithography, chemical vapour deposition, sputtering, electron-beam deposition, etc.

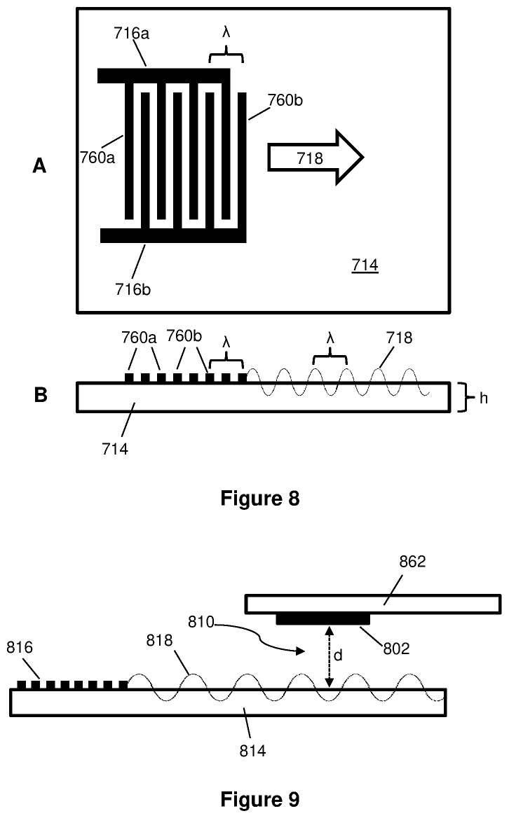

In principle, a single electrode coupled to a piezoelectric substrate can induce a high frequency acoustic wave in the substrate when electrically actuated by a suitable electric signal, such as an RF signal. More typically, however, two or more, such as a pair of spaced apart conductive electrodes are coupled to the piezoelectric substrate portion in a configuration and relative arrangement suitable to generate the desired waveform. In some embodiments, a pair of interdigitated electrodes, in which each electrode comprises multiple “fingers” alternatively interspersed with those of the other electrode as seen in FIGS. 1 and 8, is located on a surface of the piezoelectric substrate portion. Such an arrangement is particularly suitable to generate a surface acoustic wave (SAW) or a surface reflected bulk wave (SRBW) in a piezoelectric substrate.

In other embodiments, a pair of electrodes is configured as strips, located on the same or opposite surfaces of the piezoelectric substrate portion. Such an arrangement may be suitable to propagate a bulk wave (such as a Lamb wave) across a piezoelectric substrate. Other suitable electrode shapes may include L-shaped electrodes, one or more spot electrodes, line electrodes, curved electrodes or circular electrodes. A wide range of electrode configurations may be suitable when electrically actuated by a power supply at a resonance frequency of the piezoelectric substrate. These may include the simple electrode configurations suitable for generating Lamb waves and surface acoustic waves in single crystal piezoelectric substrates as disclosed in WO2015/054742.

The high frequency acoustic wave which propagates across the acoustically transmissive substrate in use generally has a frequency which is too high to induce cavitation in an aqueous electrolyte proximate the substrate, and is thus well above the power ultrasound range of 20 KHz to 100 KHz. The frequency is thus at least 1 MHz, and in some embodiments the high frequency acoustic wave has a frequency of above 1 MHz such as at least 1.5 MHz, or at least 2 MHz, or at least 3 MHz, or at least 5 MHz, such as about 10 MHz or greater. Suitably, the frequency may be in the range of 1 MHz to 10 GHz, or 3 MHz to 1 GHz, or 5 MHz to 100 MHz.

FIG. 8 depicts in plan view (A) and side view (B) an interdigitated transducer comprising a pair of interdigitated electrodes 716a and 716b on piezoelectric plate substrate 714. Each electrode comprises a plurality of interspersed fingers 760a and 760b respectively. When electrically actuated with an AC signal at its resonance frequency, the IDT causes an acoustic wave 718 to propagate across the plate substrate. For a rectangular IDT, the acoustic wavelength (λ) of the waves is defined by the pitch of adjacent electrode fingers on the same electrode (or four times the width of each finger). The frequency of the acoustic waves (f) is related to λ by the equation:

λ=c/f

where c is the speed of sound in the plate medium. A suitable IDT can thus be designed to produce a target acoustic wave frequency. For any given device, the actual value of λ can be determined by laser Doppler vibrometry.

The form of waves propagated through an acoustically transmissive plate substrate is dependent on the relationship between the acoustic wavelength (λ) and the thickness of the plate (h), as seen in FIG. 8. If h/λ is substantially greater than 1, such as greater than 2 and preferably greater than 3, the acoustic waves can be considered as approximating surface acoustic waves (SAWs or Rayleigh waves). A SAW propagates only on the surface of an acoustically transmissive substrate, attenuating to extinction through the substrate thickness within about 2λ from the surface, so that the acoustic wave is not affected by bulk resonances or internal reflections. If h/λ is substantially less than 1, such as less than ½ and preferably less than ⅓, the acoustic waves can be considered as approximating Lamb waves. In the intermediate region, where h/λ is in the order of 1, such as between ⅓ and 3, or between ½ and 2, the acoustic waves can be considered as hybrid waves which comprise both a surface wave component and a bulk wave component. Such waves have been classified as “surface reflected bulk waves” (SRBWs) by Rezk et al (Adv. Mater. 2016, 28, 1970-1975), and are described as such herein.

The high frequency acoustic waves propagated across the acoustically transmissive substrate according to the present disclosure may comprise SAWs, SRBWs or Lamb (bulk) waves. Piezoelectric transducers propagating Lamb waves may be simpler to produce, and may thus be preferred in some implementations. However, Lamb waves are considered to provide the least stimulation to a fluid in contact with substrate. Thus, in some embodiments, the high frequency acoustic waves propagated across the acoustically transmissive substrate comprise SAWs or SRBWs. To achieve this, the relationship between the thickness of the piezoelectric portion (h) and the acoustic wavelength (λ) of the high frequency acoustic wave propagating across the piezoelectric substrate portion may be such that h/λ is greater than ⅓, and is preferably greater than ½ and more preferably greater than 1.

In some embodiments, the high frequency acoustic waves propagated across the acoustically transmissive substrate comprise SRBWs. To achieve this, h/λ may be between ⅓ and 3, such as between ½ and 3, or between 1 and 2. Advantageously, such types of acoustic waves are believed to produce the highest degree of stimulation of the liquid electrolyte proximate the acoustically transmissive substrate, while still requiring only a low power input to electrically actuate the conductive electrodes. The inventors have found that excellent electrolysis results were obtained when stimulating the liquid electrolyte proximate the working electrode with SRBWs, and attribute the results to the reinforcement of the surface wave component by the reflected bulk wave component, with the two components cooperating to oscillate the substrate surface and/or working surface with maximal amplitude.

A particular advantage of embodiments of the electrolytic cell disclosed herein is the inherently low power input required to propagate high frequency acoustic waves across an acoustically transmissive substrate compared to electrolytic cells which utilise power ultrasound bulk transducers to propagate low frequency ultrasonic waves into the electrolyte, typically to induce cavitation. In some embodiments, the power input, normalised to the surface area of the acoustically transmissive substrate, is less than 20 W/cm², or less than 10 W/cm², or less than 5 W/cm², such as less than 1 W/cm².

Despite this low power input, and the short propagation distance (attenuation length) into the electrolyte associated with high frequency (MHz-range) acoustic waves, the inventors have surprisingly found substantial enhancements in electrolytic production efficiency when the working electrode is placed on or near to the acoustically transmissive substrate—thus providing a good acoustic power density at the electrode-electrolyte interface. This contrasts with the use of power ultrasound which is used in some prior art arrangements, despite the power input penalty, to maximise the acoustic propagation distance through the electrolyte and to cavitate the electrolyte.

Without wishing to be limited by any theory, the inventors propose that one significant contributor to the improved electrolytic results obtained in aqueous electrolytes is the capacity of the high frequency acoustic wave propagating across the acoustically transmissive substrate to disrupt the hydrogen bonding network of water molecules in the electrolyte proximate the acoustically transmissive substrate, and particularly at the working electrode-electrolyte interface. This effect has been observed and quantified with Raman spectroscopy (see Example 8). Therefore, in some embodiments, the high frequency acoustic wave increases the fraction of frustrated water and/or the fraction of free water in the aqueous electrolyte at the working electrode-electrolyte interface, relative to the fractions of these species under silent conditions. In some embodiments, the high frequency acoustic wave increases the fraction of frustrated water and/or the fraction of free water in the aqueous electrolyte at the working electrode-electrolyte interface by at least 50%, such as at least 100%, relative to the fractions of these species under silent conditions.

As used herein, free water refers to water molecules that do not participate in a hydrogen bonding network. The fraction of free water may be calculated by (i) measuring the Raman spectrum of the aqueous electrolyte, (ii) deconvoluting the Raman spectrum in the range of 3000-3800 cm⁻¹ into at least four Gaussian peaks, including a peak of highest frequency at about 3624 cm⁻¹ corresponding to free water, and (iii) calculating the peak area of the Gaussian peak at 3624 cm⁻¹ as a fraction of the summed peak areas of all the Gaussian peaks. In some embodiments, five Gaussian peaks at about 3055 cm⁻¹, 3230 cm⁻¹, 3392 cm⁻¹, 3520 cm⁻¹ and 3624 cm⁻¹ may be deconvoluted.

As used herein, frustrated water refers to free water (as defined above) and water weakly bound within a disrupted, trihedrally-coordinated structure. The fraction of frustrated water may be calculated by (i) measuring the Raman spectrum of the aqueous electrolyte, (ii) deconvoluting the Raman spectrum in the range of 3000-3800 cm⁻¹ into at least four Gaussian peaks, including two highest frequency peaks at about 3624 cm⁻¹ and 3520 cm⁻¹, and (iii) calculating the combined peak area of the Gaussian peaks at 3624 cm⁻¹ and 3520 cm⁻¹ as a fraction of the summed peak areas of all the Gaussian peaks. In some embodiments, five Gaussian peaks at about 3055 cm⁻¹, 3230 cm⁻¹, 3392 cm⁻¹, 3520 cm⁻¹ and 3624 cm⁻¹ may be deconvoluted.

### Working Electrode

The electrolytic cell according to the present disclosure comprises a working electrode, which is either located on the acoustically transmissive substrate or spaced apart from the acoustically transmissive substrate by the liquid electrolyte. As used herein, a working electrode is an electrode of the electrolytic cell where the faradaic reaction responsible for producing the electrolytic reaction product (the production efficiency of which is enhanced as disclosed herein) occurs.

The working electrode may suitably be either a cathode or an anode, and the composition of the working electrode may depend on the desired electrolytic reaction. For example, the working electrode may comprise an electrocatalyst for the electrolytic half-reaction which will take place on the working electrode, with the electrocatalyst at least present at the working surface. Suitable electrode compositions may include a metallic composition or metal compound, for example a metal oxide or metal sulfide. If the working electrode is to be a cathode in water electrolysis, the working electrode may comprise an HER electrocatalyst. Suitable HER electrocatalysts include, but are not limited to, gold, platinum, titanium, titanium dioxide, molybdenum disulphide, graphene, and aluminium. In other embodiments, the working electrode may comprise an OER electrocatalyst.

In some embodiments, the working electrode is located on the acoustically transmissive substrate, as disclosed herein with reference to FIGS. 1, 2, 4, 5, 6 and 7. In embodiments where the acoustically transmissive substrate is a plate and the high frequency wave comprise SBRWs or Lamb waves, the working electrode may be on either surface of the plate.

In some embodiments, the working electrode is on the same surface as the conductive electrodes. In use, the high frequency acoustic wave propagating across the acoustically transmissive substrate may propagate across and thus oscillate the working surface of the working electrode, directly stimulating the liquid electrolyte at the electrode-electrolyte interface. The inventors have demonstrated very significant improvements in electrolysis efficiency with such an arrangement, for example an improvement in current density at a target overpotential of up to fourteen-fold when conducting water electrolysis in neutral electrolytes (see Example 5). Without wishing to be limited by any theory, it is believed that a range of mechanisms may contribute to the enhancement of electrolysis efficiency in such cells, including (i) localised generation of reactive species such as H⁺ or H₃O⁺ ions through the associated electromechanical field mechanisms (see Example 5), (ii) localised disruption of the liquid electrolyte intermolecular structure, for example the hydrogen bonding network in an aqueous electrolyte, thereby producing weakly bound or free water molecules (“frustrated water”; see Example 8), (iii) enhanced bubble detachment from the working surface at much smaller bubble sizes, due to localised convective flows (see Example 6) and (iv) improved mass transfer between the electrode-electrolyte interface and the bulk electrolyte.

The working electrode may be present as one or more layers on the surface of the acoustically transmissive substrate. As will be appreciated, the thickness of the working electrode is preferably such that the high frequency acoustic wave can propagate through the working electrode, thus oscillating its surface. In some embodiments, the thickness of the working electrode is thus less than 1 mm, or less than 100 μm, or less than 10 μm, such as less than 1 μm.

The working electrode may be formed on the surface of the acoustically transmissive substrate by deposition of one or more metallic compositions or metal compounds on the piezoelectric substrate surface in one or more deposition layers, by known techniques such as photolithography, chemical vapour deposition, sputtering, etc.

While excellent results have been obtained when the working electrode is located on the acoustically transmissive substrate, such an arrangement is not essential to obtain enhanced electrolytic efficiency. In some embodiments, therefore, the working electrode is spaced apart from the acoustically transmissive substrate by the liquid electrolyte, for example as disclosed herein with reference to FIG. 3. The liquid electrolyte may thus be arranged between and in contact with the surface of the acoustically transmissive substrate and the working surface of the working electrode.

The inventors have demonstrated significant improvements in electrolysis efficiency when using a working electrode displaced from the surface of the acoustically transmissive substrate (see Examples 10 and 11). Without wishing to be limited by any theory, it is believed that at least some of the mechanisms described herein (for the scenario where the working electrode is located on the acoustically transmissive substrate) still apply when the working electrode is spaced apart from the acoustically transmissive substrate by the liquid electrolyte.

The spacing distance between the working electrode and the acoustically transmissive substrate is preferably small, thus maximising the effect of the acoustic stimulation on the electrolytic reaction taking place proximate the working surface of the working electrode. When a high frequency acoustic wave, such as a SAW, propagates across an acoustically transmissive substrate in contact with a liquid, the stimulation of the liquid by the oscillating surface propagates a corresponding beam (or jet) of sound into the liquid which attenuates with increasing distance through the liquid. The attenuation distance of the beam is inversely related to the frequency of the high frequency acoustic wave. Using one measure of attenuation distance (Xₛ, the location of maximum velocity within the jet), the distance that the jet is propagated into water by SAWs on a lithium niobate chip has been estimated as about 10-17 mm and 6 mm for a frequency of 20 and 54 MHz respectively (Dentry et al, Physical Review E 89, 013203, 2014), about 20 mm can be expected at 10 MHz, and still greater attenuation distances can be expected at lower MHz frequencies. In some embodiments, the working surface of the working electrode is within the attenuation distance, as determined by Xₛ, at the relevant acoustic frequency.

In some embodiments, the working electrode is spaced apart from the acoustically transmissive substrate by a distance through the liquid electrolyte of no more than 100 mm, or no more than 30 mm, or no more than 20 mm, or no more than 10 mm, such as about 5 mm or less.

FIG. 9 depicts piezoelectric substrate 814 with conductive electrodes (e.g. IDT electrodes) 816 located thereon. Working electrode 802, optionally formed on a supportive substrate 862, is spaced apart from piezoelectric substrate 814 by distance d, with liquid electrolyte 810 arranged between the surface of piezoelectric substrate 814 and the working surface of working electrode 802. In use, high frequency acoustic wave 818 propagates across piezoelectric substrate 814, thus directly stimulating the liquid electrolyte in contact with the piezoelectric substrate. Although working electrode 802 is displaced from the surface of piezoelectric substrate 814, the stimulation of the liquid electrolyte nevertheless increases the electrolysis efficiency when conducting an electrolysis reaction. To maximise the extent of the enhancement, distance d may be minimised to the extent possible, so that liquid electrolyte 810 is stimulated proximate to the working surface of working electrode 802. In some embodiments, d is no more than 100 mm, or no more than 30 mm, or no more than 20 mm, or no more than 10 mm, such as about 5 mm or less.

The working electrode may be formed on the surface of a supportive substrate by deposition of one or more metallic compositions or metal compounds on the piezoelectric substrate surface in one or more deposition layers, by known techniques such as photolithography, chemical vapour deposition, sputtering, etc. However, a wider range of working electrode configurations may be suitable when the working electrode is spaced apart from the acoustically transmissive substrate, since it is not required that the propagating high frequency acoustic wave passes through the working surface of the working electrode. For example, the working electrode may be a rod-type or plate-type electrode held in the electrolyte a suitable distance from the acoustically transmissive substrate.

### Other Electrodes

The electrolytic cell according to the present disclosure comprises a counter electrode. As used herein, a counter electrode is an electrode of the electrolytic cell where a faradaic reaction occurs to balance the charge of the faradaic reaction occurring at the working electrode. If the working electrode is a cathode, the counter electrode is an anode (and vice versa). The electrolytic cell may be a two-electrode system, i.e. the only electrodes are the working and counter electrodes. Alternatively, the electrolytic cell may further comprise other electrodes such as a reference electrode.

The counter electrode may be of conventional design and function in the electrolytic cell. However, it is contemplated that the counter electrode may also be located on an acoustically transmissive substrate or spaced apart from an acoustically transmissive substrate by the liquid electrolyte. The acoustically transmissive substrate may be the same or different as that which acoustically enhances the electrolytic reaction proximate the working electrode. Advantageously, the overall electrolytic cell performance may be enhanced by acoustically stimulating both electrodes. For example, this may be particularly useful in water electrolysis where gas bubbles are generated on the surface of each electrode.

### Liquid Electrolyte

The electrolytic cell according to the present disclosure comprises a liquid electrolyte in contact with a working surface of the working electrode. The same liquid electrolyte may also be in contact with the counter electrode. However, it will be appreciated that is not necessarily the case. For example, separate anolytes and catholytes may be used in an electrolytic cell, separated by an ion-permeable membrane.

The liquid electrolyte may be of any suitable composition, including aqueous electrolytes, organic electrolytes (organic solvent carriers) and ionic liquid electrolytes. In some embodiments, the liquid electrolyte is an aqueous electrolyte. The aqueous electrolyte may have any suitable pH for the desired electrolytic reaction, including an acidic pH (e.g. pH<5), a neutral pH (e.g. pH 5-9) or an alkaline pH (pH>9). The inventors have demonstrated enhancements in water electrolysis in each of these electrolytes (see Example 9). In some embodiments, the aqueous electrolyte has a pH of between 5 and 9, such as between 6 and 8. The enhancement of water electrolysis at such pH values is of particular interest as it has previously been considered challenging to achieve commercially significant current densities in neutral electrolytes.

The liquid electrolyte comprises one or more species to be electrolytically reacted proximate the working electrolyte, thereby producing the desired electrolytic reaction product. In water electrolysis, these species are water and ionised forms thereof (H⁺, H₃O⁺, OH⁻). However, in other electrolytic reactions, it will be appreciated that the reacting species may be one or more molecular or ionic species present in, for example dissolved in, the liquid electrolyte.

### Power Supplies

The electrolytic cell according to the present disclosure comprises one or more power supplies configured (i) to apply a potential between the working electrode and the counter electrode sufficient to electrolytically react a species in the liquid electrolyte, thereby producing an electrolytic reaction product proximate the working electrode, and (ii) to electrically actuate the one or more conductive electrodes, thereby propagating a high frequency acoustic wave having a frequency of at least 1 MHz across the acoustically transmissive substrate. In some embodiments, the power supplies for these functions are separate. However, it will be appreciated that they may be integrated into a single power supply device.

The power supply to the working electrode and the counter electrode may be a conventional power supply for an electrolytic cell, such as a water electrolysis cell. This power supply is typically a direct current power source. Optionally, the power supply may be derived from a photovoltaic solar cell or other renewable energy source. The power source is capable of providing and typically sustaining the requisite potential between the working and counter electrodes as current is passed through the cell. For a water electrolysis cell, the potential at the working electrode is advantageously reduced according to the principles disclosed herein, but (in the case of the cathode) may nevertheless be greater than (more negative than) −1.5V vs RHE (RHE=reversible hydrogen electrode) in some implementations. In some embodiments, however, the potential at the working electrode (in the case of the cathode) is no greater than (more negative than) −1.5V vs RHE, or no greater than (more negative than) −1V vs RHE.

The power supply to electrically actuate the conductive electrodes is typically an alternating current power source, at the resonant frequency of the electrodes coupled to the acoustically transmissive substrate.

### Flow Cell for Water Electrolysis

In some embodiments, the electrolytic cell is a flow cell for water electrolysis. One such embodiment has already been disclosed herein, i.e. electrolytic cell 300 as described with reference to FIG. 4.

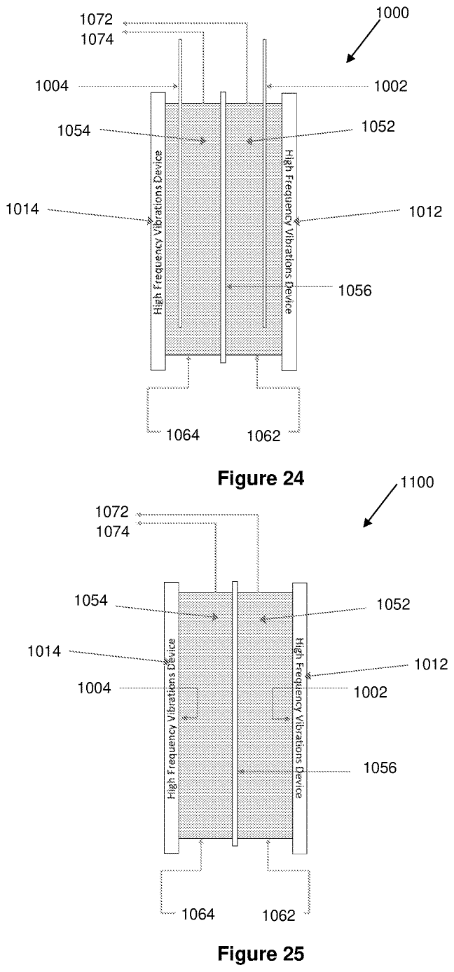

An electrolytic flow cell for water electrolysis 1000 according to other embodiments of the invention will be described with reference to FIG. 24. Cell 1000 comprises cathode 1002 and anode 1004, connected to a power source (not shown) which is configured to apply a potential between the electrodes sufficient to electrolytically split water and thus produce electrolytic reaction products proximate cathode 1002 (i.e. H₂) and anode 1004 (i.e. O₂). Cathode 1002 may thus comprise an electrocatalyst for the HER, while anode 1004 may comprise an electrocatalyst for the OER. The electrodes may have any suitable configuration, for example they may independently either be plate-like, perforated or porous.

Cathode compartment 1052 is separated from anode compartment 1054 by a proton exchange membrane 1056 (e.g. fabricated from an ionomer such as Nafion) or other semi-permeable membrane which prevents bulk mixing of the electrolyte present in each compartment while facilitating passage of ionic species needed to maintain charge neutrality in the cell. In use, separate aqueous electrolyte streams are flowed through cathode compartment 1052 (catholyte 1062) and anode compartment 1054 (anolyte 1064). Catholyte 1062 and anolyte 1064 may be aqueous electrolytes of any suitable pH, such as an acidic pH, a neutral pH (pH 5-9) or an alkaline pH, with the same or different composition, preferably the same. H₂ formed on cathode 1002 is thus carried out of the cell in catholyte outlet stream 1072, while O₂ formed on anode 1004 is carried out of the cell in anolyte outlet stream 1074. Preferably, the direction of electrolyte flow is upward, thus allowing gas bubbles disengaging from the electrodes to rise upward with the direction of electrolyte flow. Mixing of the product gases is avoided or minimised due to the vertical flow direction and membrane 1056 which prevents bulk mixing of anolyte and catholyte.

Cell 1000 further comprises piezoelectric substrates 1012 and 1014, and electrodes and power supplies (not shown) configured to propagate a high frequency acoustic wave across piezoelectric substrates 1012 and 1014 as described herein. Optionally, the piezoelectric substrates may form part of the outer walls of the flow cell, as shown. Cathode 1002 is spaced apart from piezoelectric substrate 1012 by a small distance, with catholyte 1052 present in the gap. Similarly, anode 1004 is spaced apart from piezoelectric substrate 1014 by a small distance, with anolyte 1054 present in the gap. For both electrodes, the distance between electrode and piezoelectric substrate is preferably no more than 10 mm, or no more than 5 mm, or no more than 1 mm.

In use, high frequency acoustic waves propagate across piezoelectric substrates 1012 and 1014, thus stimulating the liquid electrolyte between the piezoelectric substrates and the electrodes. This increases the electrolysis efficiency of both the HER and the OER, enhancing the production rate of the overall water splitting reaction according to the principles disclosed herein.

An electrolytic flow cell for water electrolysis 1100 according to other embodiments of the invention will be described with reference to FIG. 25. Electrolytic flow cell 1100 is similar to electrolytic flow cell 1000, and similarly numbered items are the same in both cells. However, in cell 1100, cathode 1002 is formed directly on the surface of piezoelectric substrate 1012, and anode 1004 is formed directly on the surface of piezoelectric substrate 1014. The high frequency acoustic wave propagated across the piezoelectric substrates thus directly stimulates (oscillates) the working surface of the electrodes, and thus the aqueous electrolytes at the electrode-electrolyte interface, according to the principles disclosed herein.

### Method of Electrolysis

The present invention further relates to a method of electrolysis. The method comprises contacting a liquid electrolyte with a working surface of a working electrode and propagating a high frequency acoustic wave having a frequency of at least 1 MHz across an acoustically transmissive substrate. The working electrode is either located on the acoustically transmissive substrate or spaced apart from the acoustically transmissive substrate by the liquid electrolyte. A potential is applied between the working electrode and a counter electrode sufficient to electrolytically react a species in the liquid electrolyte, thereby producing an electrolytic reaction product proximate the working electrode. The propagation of the high frequency acoustic wave across the acoustically transmissive substrate stimulates the liquid electrolyte, thereby increasing the production efficiency of the electrolytic reaction product.

In some embodiments, propagating the high frequency acoustic wave across the acoustically transmissive substrate comprises electrically actuating one or more conductive electrodes coupled to a piezoelectric substrate portion of the acoustically transmissive substrate.

In some embodiments, the method of electrolysis is a method of water electrolysis to produce H₂ as the electrolytic reaction product. The liquid electrolyte is thus an aqueous electrolyte, which in some embodiments may be a neutral electrolyte (pH 5 to 9). In some such embodiments, the potential at the cathode is no greater than (more negative than) −2.5V vs RHE, or no greater than (more negative than) −1.5V vs RHE, such as no greater than (more negative than) −1.0V vs RHE. The potential applied between the cathode and anode (i.e. the potential difference) must be at least 1.23 V (for a 100% efficient system), but in practice will be higher. Nevertheless, the potential difference may advantageously be reduced due to the acoustic stimulation. In some embodiments, the potential applied between the cathode and anode is thus less than 2 V.

It will be appreciated that other relevant features of the method are generally as described herein in the context of the electrolytic cell of the invention.

### An Electrode Apparatus for an Electrolytic Cell

The present invention further relates to an electrode apparatus for an electrolytic cell. The electrode apparatus comprises an acoustically transmissive substrate comprising at least a piezoelectric substrate portion and a working electrode located on the acoustically transmissive substrate. The working electrode comprises a working surface for contact with a liquid electrolyte in an electrolytic cell. One or more conductive electrodes are coupled to the piezoelectric substrate portion and configured to propagate a high frequency acoustic wave having a frequency of at least 1 MHz across the acoustically transmissive substrate when electrically actuated.

The electrode apparatus is adapted for use in embodiments of the electrolytic cell previously described herein where the working electrode is located on the acoustically transmissive substrate. It will therefore be appreciated that other relevant features of the electrode apparatus are generally as described herein in the context of the electrolytic cell of the invention.

### EXAMPLES

The present invention is described with reference to the following examples. It is to be understood that the examples are illustrative of and not limiting to the invention described herein.

### Example 1. Preparation of Acoustic Wave Generator and Working Electrode on a Piezoelectric Substrate

An acoustic wave generator was produced by photolithographically patterning an interdigital transducer (IDT) electrode consisting of 30 finger pairs of 10 nm and 200 nm thick titanium and gold layers with an aperture size of 5.6 mm on a 28×47×0.5 mm single-crystal piezoelectric (128° Y-rotated, X-propagating lithium niobate; LiNbO3) substrate (Roditi Ltd., London, UK). The pitch of the fingers on each electrode, i.e. the distance between adjacent electrode fingers on the same electrode, was 0.4 mm.

A 0.1 cm² circular working electrode (WE) (0.36 cm diameter) was then patterned from the same material (10 nm and 200 nm thick titanium and gold) on the substrate within the aperture width of the IDT such that it lies in the wave propagation pathway 4 mm from the IDT.

The thickness of the piezoelectric substrate (h) is 0.5 mm and the acoustic wavelength of waves propagated by the IDT (λ, equal to the pitch), is 0.4 mm. Thus, the value of h/λ is about 1.2. The high frequency acoustic wave is thus expected to be a SRBW. The resonance frequency of the IDT is expected to be 10 MHz (based on the speed of sound in the lithium niobate substrate, being about 3980 m/s.

Powder x-ray diffraction (Bruker D8 General Area Detector Diffraction System, GADDS, Bruker Pty. Ltd., Preston VIC, Australia) was carried out to determine the crystalline phases of the sputter-coated gold electrode layer under Cu Kα radiation at 40 mA and 40 kV (λ=1.54 Å) over a 2θ range of 20°-90° with a step size of 0.01° and scan rate of 2.6° min⁻¹. The X-ray diffraction (XRD) pattern indicated its polycrystalline structure with a {311} orientation plane, as revealed by the strong (311) diffraction peak along with weaker (111), (200) and (220) peaks.

### Example 2. Preparation of Electrochemical Cell

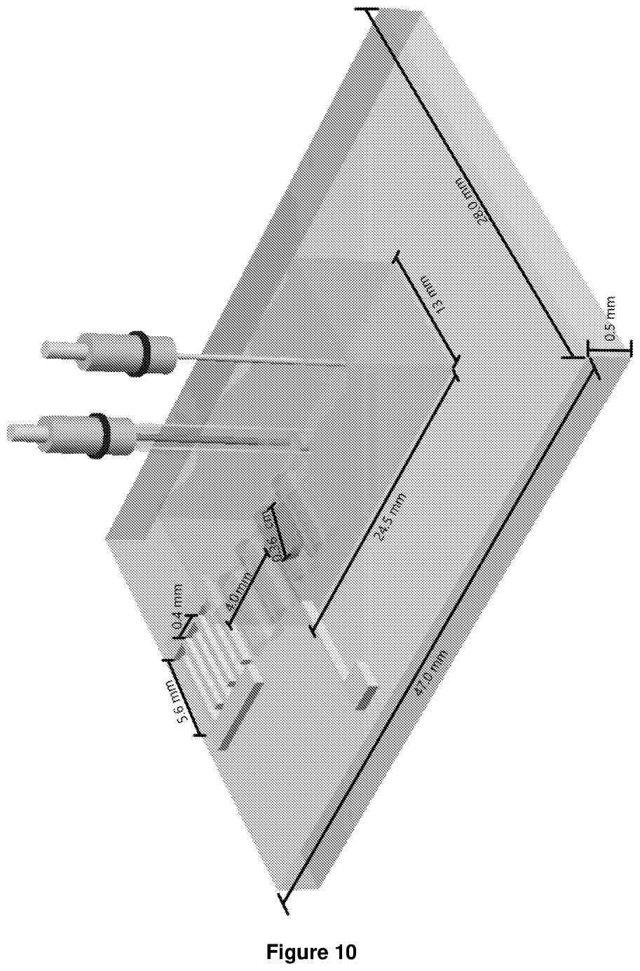

An electrochemical cell as schematically depicted in FIG. 1 was produced as follows. A 13.0 mm×24.5 mm rectangular electrolyte chamber (internal dimensions 9 mm×20.5 mm) was constructed by joining walls laser cut from 2 mm thick glass sheets with glass glue (Nano470™, Safe Light Technology, Varsity Lakes, QLD, Australia) and thoroughly cleaned. The base of the chamber was then attached to the piezoelectric substrate with patterned transducer and cathode (as produced in Example 1), using silicone (Parfix All Purpose, Clear; Bunnings, VIC, Australia) with a thickness of approximately 0.5 mm and dried at 50° C. for 3 hrs. The IDT remained outside and the WE inside the resultant chamber. The chamber was then covered with a custom 3D printed lid in which the counter (CE) and reference (RE) electrodes were mounted. The CE was a 0.5 mm diameter coiled platinum wire (temper-annealed, 99.95%, Advent Research Materials Ltd., Oxford, UK) and the RE was an Ag/AgCl in 1 M KCl (CH Instruments Inc., Austin, TX, USA). The chamber was thoroughly cleaned by rinsing with copious amounts of MilliQ water (18.2 M/cm, Merck Millipore, Bayswater, VIC, Australia). Relevant dimensions of the cell are shown in FIG. 10.

### Example 3. Generation and Characterisation of the Acoustic Wave

To propagate an acoustic wave along and through the surface of the LiNbO₃ substrate, the IDT was connected to a radio frequency (RF) source comprising a signal generator (SML01, Rhode & Schwarz GMbbH & Co. KG, Munich, Germany) and amplifier (ZHL-5W-1+, Mini-Circuits, Brooklyn, NY, USA). An AC electrical signal at the resonance frequency (10 MHz) was then applied to the transducer. The resultant acoustic wave shape was imaged by laser Doppler vibrometer (LDV; UHF-120, Polytec Inc., Irvine, CA).

FIG. 1 (insets 120, 122) shows the laser Doppler vibrometry scans of the acoustic waves (20 dBm) propagating through the WE (indicated in dashed outline 124). The vibrometry scans is consistent with the propagation of surface reflected bulk waves across the piezoelectric chip.

### Example 4. Preparation of Electrolytes

A first neutral electrolyte solution comprising 0.1 M sodium phosphate buffer was prepared by dissolving 0.31 g of mono-basic sodium phosphate (NaH₂PO₄, 99.0%; Merck Millipore, Baywater, VIC, Australia) and 1.09 g of disodium hydrogen phosphate (Na₂HPO₄, 99.0%; Sigma-Aldrich Pty. Ltd., Castle Hill, NSW, Australia) in 100 ml of pure water (sterile filtered molecular biology reagent, Sigma-Aldrich Pty. Ltd, Castle Hill, NSW, Australia).

A second neutral electrolyte was prepared with 0.1 M potassium chloride (KCl, 99.0%, Sigma-Aldrich Pty. Ltd., Castle Hill, NSW, Australia) dissolved in pure water (sterile filtered molecular biology reagent, Sigma-Aldrich Pty. Ltd, Castle Hill, NSW, Australia).

An acidic electrolyte of 0.5 M H₂SO₄ was prepared by diluting 2.72 ml of sulphuric acid (H₂SO₄, 98%, Thermo Fisher Scientific, Taren Point, NSW, Australia) in 97.28 ml of pure water (sterile filtered molecular biology reagent, Sigma-Aldrich Pty. Ltd, Castle Hill, NSW Australia).

An alkaline electrolyte was prepared with 1 M potassium hydroxide (KOH, 99.0%, Sigma-Aldrich Pty. Ltd., Castle Hill, NSW, Australia) dissolved in pure water (sterile filtered molecular biology reagent, Sigma-Aldrich Pty. Ltd, Castle Hill, NSW, Australia).

A three-point calibrated pH meter (InLab Ultra-Micro-ISM, Mettler-Toledo Ltd.) was used to measure the electrolyte pH.

### Example 5. Electrochemical Measurements in Neutral Electrolytes

The electrochemical performance of the electrochemical cell of Example 2 in electrolysis reactions was evaluated using a three-electrode set-up using (i) the Pt wire CE, (ii) the Ag/AgCl in 1 M KCl RE, and (iii) the polycrystalline gold WE as produced on the piezoelectric substrate in Example 1. The electrolyte volume was 1 ml. Nitrogen gas was bubbled through the electrolyte for 20 mins prior to the electrochemical studies to purge dissolved oxygen. Each electrode was connected to a potentiostat (VSP-128, BioLogic, Seyssinet-pariset, France). All experiments were conducted at ambient temperature (c.a. 25° C.) and the result analysed using EC-Labs® software (v11.25, BioLogic, Seyssinet-pariset, France). Linear sweep voltammetry (LSV) was performed with a scan rate of 10 mV s⁻¹. The measured or applied potentials were converted to reversible hydrogen electrode (RHE) values via Eq (1):

E_{RHE}=E_{(Ag/AgCl)}+0.197 V+pH×0.059 V (1)

and iR-corrected using;

E_{iR}=E_{RHE}−iRᵤ (2)

where i is the measured current density and Rᵤ is the electrolyte resistance (the ionic electrolyte resistance between the tip of the reference electrode and the working electrode surface). The electrolyte resistance (Rᵤ) of the 0.1 M sodium phosphate electrolyte (pH 7.2) under silent conditions and under acoustical stimulation at varying power levels (10 dBm, 15 dBm, 20 dBm) was determined from electrochemical impedance spectroscopy (EIS; 100 kHz-0.1 Hz, 10 mV amplitude) collected at three constant voltages beyond the onset potential (i.e., larger than the potential delivering-10 mA cm⁻²; as described in Anantharaj et al., ChemElectroChem, 7, 2297-2308, 2020) and fitted using EC-Labs® software (v11.25, BioLogic, Seyssinet-pariset, France). The uncompensated resistance Rᵤ values, obtained from fitted Nyquist plots, are shown in Table 1 below.

TABLE 1

| | Uncompensated | n (number of experiments |
|---|---|---|
| Condition | resistance Rᵤ (Ω) | used for the fit) |
| Silent | 205.2 ± 2.6 | 3 |
| 10 dBm | 186.5 ± 4.7 | 3 |
| 15 dBm | 124.6 ± 7.0 | 3 |
| 20 dBm | 86.5 ± 4.1 | 4 |

These uncompensated Rᵤ values were then averaged for each condition and applied to subsequent LSV experiments at 100% iR correction under a current density of −10 mA cm⁻² and 80% iR correction beyond −10 mA cm⁻² using Eq. (2) (Anantharaj et al, Energy Environ. Sci., 11, 744-771, 2018).

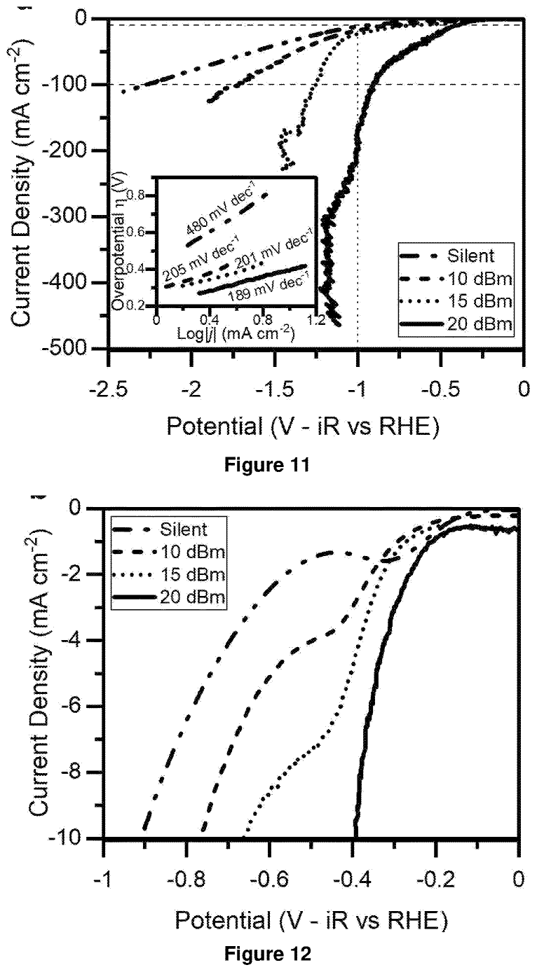

Linear sweep voltammograms (LSV) obtained with the 0.1 M sodium phosphate electrolyte (pH 7.2) under silent conditions and under acoustical stimulation at varying power levels (10 dBm, 15 dBm, 20 dBm) are shown in FIG. 11 and in FIG. 12 (a magnification of the low current density region of FIG. 11). The inset in FIG. 1 plots the Tafel slopes for each condition, showing a decrease in the Tafel slope with increasing acoustic power. It is evident that the high frequency acoustic stimulation decreased the overpotential and thus the production rate of hydrogen, with the extent of the effect dependent on the power. The Tafel plot reveals a significant decrease in the Tafel slope from 480 mV dec⁻¹ under silent conditions to 205, 201 and 184 mV dec⁻¹ with the power at 10, 15 and 20 dBm respectively.

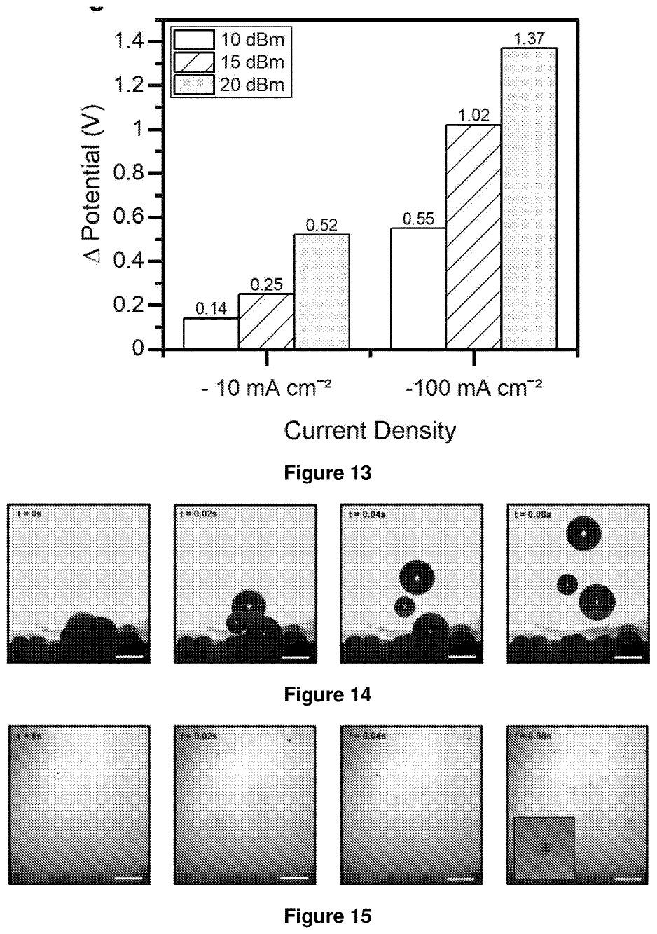

The overpotential is thus reduced by up to 0.52 V and 1.37 V at current densities of −10 and −100 mA cm⁻² respectively, as seen in FIG. 13. At 20 dBm (0.3 W) applied power, only a 400 mV overpotential is required to achieve a current density of −10 mA cm⁻². This is approximately half of that reported for Pt in neutral conditions (Strmonik et al, Nat. Chem.; 2013, 5, 300-306; Shinagawa et al, ChemElectroChem 2014, 1, 1497-1507), suggesting that acoustically stimulated gold electrodes have superior electrochemical performance to even Pt electrodes under neutral conditions. At an overpotential of −1 V, the current density increases almost fourteenfold under acoustic stimulation (from −11:8 mA cm⁻² to −164:4 mA cm⁻²), thus reaching industrially relevant ranges.

The observed overpotential (ηₜₒₜₐₗ) in HER is commonly considered to consist of three contributions, as set out in Eq. (1):

ηₜₒₜₐₗ=η_{act}+η_{Ω}+η_{conc} (3)

where η_{act} is the activation overpotential that governs the kinetics of the reaction, η_{act} is the Ohmic overpotential corresponding to the electrical resistance of the cell, and η_{conc} is the overpotential associated with the mass transport limitations in the system.

At low current densities (when ionic diffusion to and from the bulk electrolyte is least limiting) and prior to the onset of bubble nucleation, η_{act} is expected to be the dominant contributor. The low current density region, as seen in FIG. 12, is thus helpful to understand the effect of high frequency acoustic stimulation on η_{act}.

Under silent conditions, a plateau in the current density-potential response curve (from about −400 mV) is observed. This plateau is a known consequence of the exhaustion of available H⁺ and H₃O⁺ ions in the electrolyte, with these species only being replenished upon dissociation of water (H₂O) molecules at higher applied potentials. The disappearance of the plateau under high frequency acoustic stimulation is thus ascribed to the localised generation of H⁺ or H₃O⁺ ions at the electrode/electrolyte interface, as previously reported by Rezk et al J. Phys. Chem. Lett. 2020, 11, 4655-4661. Without wishing to be limited by any theory, it is believed that the large evanescent electric field associated with electromechanical coupling of the acoustic waves to the piezoelectric substrate, at least in the highly polarised regions defined by the nanoscale amplitudes of the high frequency acoustic waves, exceeds the threshold intensity for self-ionisation of pure water.

At high current densities, η_{Ω} and η_{conc} are expected to be the dominant contributors to the total observed overpotential ηₜₒₜₐₗ due to the build-up of bubbles on the electrode surface. Without wishing to be limited by any theory, the observed effect of high frequency acoustic stimulation at high current densities, as seen in FIG. 11, is ascribed to acoustic streaming (i.e. bulk liquid recirculation) which overcomes diffusive mass transfer limitations by compressing the diffusion layer and facilitates detachment and removal of bubbles which would otherwise be trapped at the working surface. This mechanism thus beneficially affects both η_{Ω} and η_{conc}.

The effect of the acoustic stimulation on η_{Ω} is also evident from the uncompensated electrolyte resistance Rᵤ values obtained in EIS experiments, as seen in Table 1. The decrease in Rᵤ with increasing acoustic power (up to 58% decrease at 20 dBm compared to silent conditions) implies faster charge transfer and higher Faradaic efficiency.

### Example 6. Bubble Imaging

To investigate the effect of high frequency acoustic stimulation on bubble generation, chronopotentiometric electrolysis experiments were conducted under silent conditions and under high frequency acoustic stimulation at varying power levels (10 dBm, 15 dBm, 20 dBm) while capturing images of the generated bubbles with a high-speed video camera (SA5, Photron Ltd, Tokyo, Japan) with a magnification lens (K2 Objective CF-4, Edmund Optics Inc., Barrington, NJ, USA) at a frame rate of 10000 frames per second and viewing the electrode surface through the glass walls of the cell. The same cell and electrolyte (0.1 M sodium phosphate; pH 7.2) were used as in Example 5, and a potentiostat (Model 1440 and v17.02 software; CH Instruments, Inc., TX, USA) was used to hold the current density at −30 mA cm⁻² while recording the images.

As representatively seen in the time series photographs of FIG. 14 at 0, 0.02 s, 0.04 s and 0.08 s, in which the scale bar denotes a length of 500 μm, bubbles formed under silent conditions grow and coalesce to reach a critical size of approximately 450 μm before their buoyancy overcomes the adhesion force and the bubbles detach from the electrode surface. By contrast, when the electrode surface is stimulated with high frequency acoustic waves at 20 dBm, as seen in FIG. 15, the bubbles grow only to about 40 μm, without coalescing, before detaching from the surface. Without wishing to be limited by any theory, it is believed that this detachment is due to the drag forces applied to the bubbles by the streaming convective flows induced by the acoustic stimulation, and the resultant suppression of bubble build-up at the electrode surface reduces the contribution to overpotential of both the electrical resistance (η_{Ω}) and the diffusion barrier (ηconc).

### Example 7. Long Term Stability of Acoustically Stimulated Electrolysis

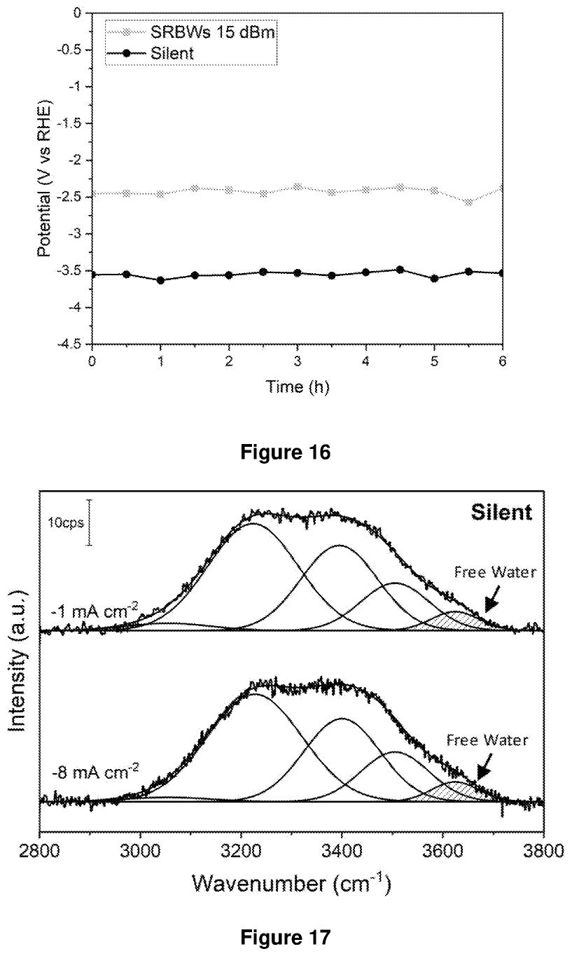

To investigate the effect of high frequency acoustic stimulation on longer-term electrolytic performance, chronopotentiometric electrolysis experiments under silent conditions and under high frequency acoustic stimulation (15 dBm) were conducted at a current density of −100 mA cm⁻² maintained during the course of 6 hour reactions. The same cell and electrolyte (0.1 M sodium phosphate; pH 7.2) were used as in Example 5, and the results are shown in FIG. 16. Under acoustic stimulation the reaction showed excellent stability at about −2.5V overpotential. A substantially reduced overpotential was thus obtained throughout the experiment in comparison to the equivalent reaction conducted under silent conditions.

In another experiment using the same experimental set-up as Example 4, LSV experiments were conducted (0-2 V) with the 0.1 M potassium chloride neutral electrolyte, under both silent and acoustically stimulated conditions (20 dBm). After the experiments, the surface of the working electrode was imaged with scanning electron microscopy (SEM; Quanta 200 ESEM, FEI, Hillsboro, OR, USA). After electrolysis under silent conditions, the surface was pitted whereas little or no damage was evident after electrolysis under acoustic stimulation. The results are consistent with the damage expected when large H₂ bubbles accumulate and detach from the electrode surface.

### Example 8. Raman Investigations of the Electrolyte-Electrode Interface

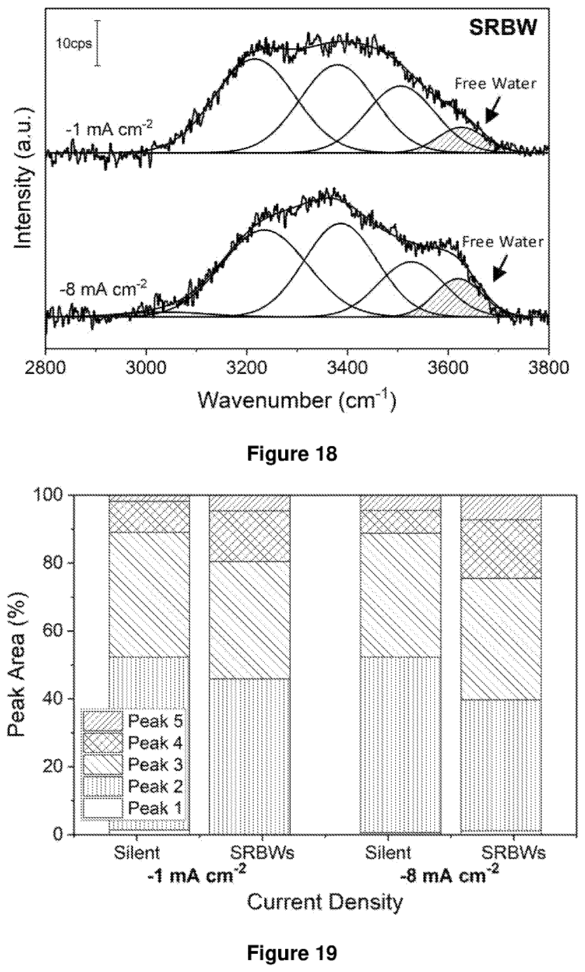

In situ Raman spectroscopy (LabRAM HR Evolution, Horiba Scientific, France SAS), conducted at 633 nm excitation (2800-3900 cm⁻¹ acquisition range) with a 10× objective and 1800 gr/mm grating, was then used to study the working electrode-electrolyte interface. All spectra were calibrated with respect to a silicon wafer at 520 cm⁻¹. Chronopotentiometric electrolysis experiments were thus conducted using the same experimental set-up as Example 4 and a neutral electrolyte (0.1 M sodium phosphate; pH 7.2) at low current densities (either −1 mA cm⁻² or −8 mA cm⁻²) to minimise interference from bubble formation on the spectroscopic analysis. Raman spectra were obtained across the wavenumber range 3000-3800 cm⁻¹, corresponding to the hydrogen bond structure of the electrolyte adjacent to the electrode-electrolyte interface, under silent conditions (FIG. 17) and under high frequency acoustic stimulation (15 dBm) (FIG. 18).

Five Gaussian peaks were deconvoluted at approximately 3055 cm⁻¹, 3230 cm⁻¹, 3392 cm⁻¹, 3520 cm⁻¹ and 3624 cm⁻¹, with the lower wavenumbers (<3400 cm⁻¹) being associated with water molecules that are strongly bound by hydrogen-bonding interactions within a tetrahedral network structure and the higher wavenumbers (>3400 cm⁻¹) being associated with water molecules that are weakly bound within a trihedrally-coordinated structure. The peak at 3624 cm⁻¹ peak corresponds to ‘free’ water molecules that do not participate in the hydrogen bond network (Holzammer et al, J. Phys. Chem. B 2019, 123, 2354-2361). FIG. 19 plots the relative peak areas of the five peaks for the four experiments (−1 mA cm⁻² or −8 mA cm⁻²; silent or 15 dBm acoustic stimulation). A modest increase in weakly-coordinated molecules (peaks 4 and 5) is seen with increasing current density under silent conditions, indicating that electrolytic reaction inherently affects the water structure to a degree. Under acoustic stimulation, substantially higher concentrations of the weakly-coordinated molecules were seen, both at low over potentials (−1 mA cm⁻²) and at overpotentials just before significant bubble generation (−8 mA cm⁻²). Notably, the concentration of ‘free’ water molecules (peak 5) and “frustrated water” (peaks 4 and 5) increase by 61% and 120% respectively when acoustically stimulated at −8 mA cm⁻², in comparison to the same current density under silent conditions.

Without wishing to be bound with any theory, it is proposed that the disruption in water structure induced by high frequency acoustic stimulation plays a significant role in the improved HER performance described herein. Freer water molecules can absorb more readily onto catalytic sites on the electrode compared to strongly bound water molecules, with the activation energy of water dissociation expected to decrease in the order of tetrahedral-coordinated water>trihedral-coordinated water>“free” water. This reduces η_{act} of the cell, making the electrolysis process more efficient.

Similar Raman spectroscopy observations were made when conducting the same experiments with deionised water as electrolyte instead of 0.1 M sodium phosphate electrolyte. The results demonstrated that the increase in “frustrated water” (peaks 4 and 5) and “free” water (peak 5) at the electrode-electrolyte interface under high frequency acoustic stimulation is not an artefact of sodium cations (when using sodium phosphate buffered electrolyte). In fact, the disruption to the intermolecular water network was more pronounced in deionised water, suggesting that increased ionic strength of the electrolyte may screen the acoustically induced electric field. Thus, the fraction of free water increased from less than 5% to more than 10% (15 dBm acoustic waves, at −2 mA/cm⁻² current density for electrolysis). This highlights the particular advantage of the methods disclosed herein when seeking to use low molarity, and particularly neutral, electrolytes.

### Example 9. Electrochemical Measurements in Acidic and Alkaline Electrolytes

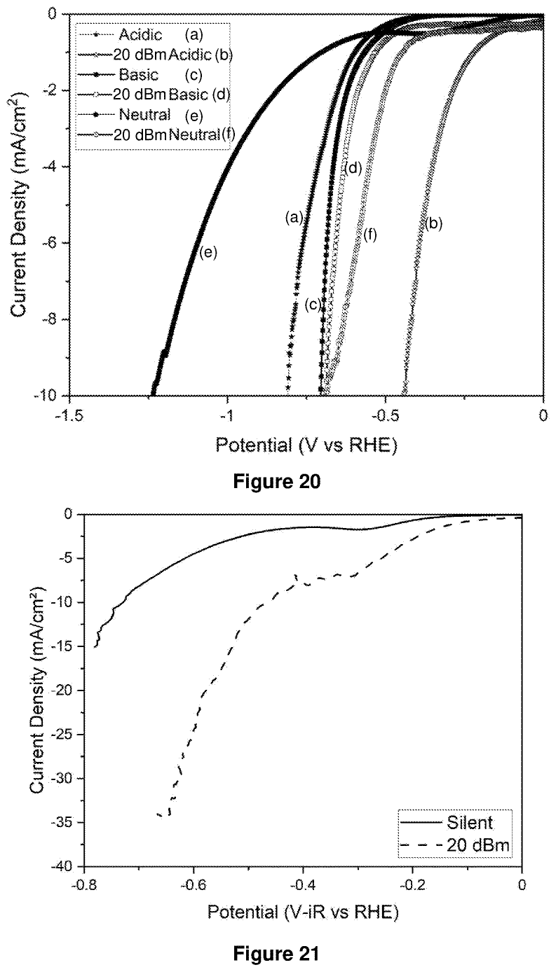

The method of Example 5 was used to investigate the effect of high frequency acoustic stimulation on water electrolysis with electrolytes of different pH. Linear sweep voltammograms (LSV) obtained with the acidic (0.5 M H₂SO₄), basic (0.1 M KOH) and neutral (0.1 M sodium phosphate; pH 7.2) electrolytes under silent conditions and under acoustical stimulation at a power level of 20 dBm are shown in FIG. 20.

As expected, substantially higher overpotential is required with the neutral electrolyte compared with the acidic and alkaline electrolytes under silent conditions. High frequency acoustic stimulation was effective to reduce the overpotential with all three electrodes, to the extent that the acoustically stimulated overpotential was less for the neutral electrode than for the acidic or alkaline electrolytes under silent conditions. The greatest effect was observed for the acidic and neutral electrolytes.

### Example 10. Working Electrode in Close Proximity to the Transducer

An electrochemical cell as schematically depicted in FIG. 3 was produced in similar manner to Example 2, except that the working electrode was a 2 mm diameter gold (Au) rod electrode (CH Instruments Inc., CHI101, Austin, TX, USA) instead of a WE patterned on the piezoelectric substrate. The electroactive working surface of the electrode is only the circular bottom surface and the inner rod, but not the sides of the rod. The configuration of the piezoelectric substrate and IDT, and the Pt wire CE and Ag/AgCl in 1 M KCl RE, remained as described in Example 2. All three electrodes were held by a custom 3D-printed lid and immersed in 1 ml of neutral (0.1 M sodium phosphate; pH 7.2) electrolyte. The end of each electrode was approximately 0.5 cm away from the piezoelectric substrate.

Linear sweep voltammograms were recorded with a potentiostat (VSP-128; BioLogic, Seyssinet-pariset, France), in similar manner to Example 5, under silent conditions or under acoustic stimulation (20 dBm). The LSV curves, plotted with a 30% iR correction factor, are shown in FIG. 21. The results show that the propagation of high frequency acoustic waves across the piezoelectric surface decreases the required overpotential (thus enhancing the hydrogen evolution reaction rate) despite the surface of the working electrode being displaced a short distance from the piezoelectric substrate.

### Example 11. High Frequency Acoustic Stimulation of the Oxygen Evolution Reaction

A 10 MHz acoustic wave generator similar to that described in Example 1 (but omitting the gold electrode) was prepared. The IDT electrode consisted of 55 finger pairs with an aperture size of 12.2 mm on a 21.8×16×0.5 mm single-crystal piezoelectric (128° Y-rotated, X-propagating lithium niobate; LiNbO3) substrate (Roditi Ltd., London, UK). The pitch of the fingers on each electrode, i.e. the distance between adjacent electrode fingers on the same electrode, was 0.4 mm. This device was used to acoustically stimulate the anode (thus enhancing the OER) in an electrochemical flow cell fabricated according to the design of cell 1000 described herein with reference to FIG. 24. The flow cell walls were fabricated from acrylic, incorporating the acoustic wave generator as one wall of the cell. The anode (i.e. the working electrode in this experiment) was positioned adjacent to the surface of the single-crystal piezoelectric substrate across which the 10 MHz acoustic wave (SRBW wave form) propagates, with a spacing (through the electrolyte in use) of between 0.5 and 3 mm. The anode working area was approximately 0.5×0.8 cm², with anode thickness of about 0.5 mm. Both a nickel anode and a stainless steel mesh anode were used in separate experiments. A commercially available graphite counter electrode (cathode; 1×1×0.5 cm), was placed at the opposite end of the cell, less than 3 cm from the anode. A reference electrode was placed in the middle of the cell. The cell volume was approximately 5 mL, and the flow rate of electrolyte could be controlled from 0 (static experiment) up to 100 ml/min.

The electrochemical performance of the cell in water splitting reactions was performed using either an alkaline electrolyte (1 M KOH) or a neutral electrolyte (0.1 M sodium phosphate buffer). Each electrode was connected to a potentiostat (VSP-128, BioLogic, Seyssinet-pariset, France). All experiments were conducted at ambient temperature (c.a. 25° C.) and the result analysed using EC-Labs® software (v11.25, BioLogic, Seyssinet-pariset, France), as described in Example 5.

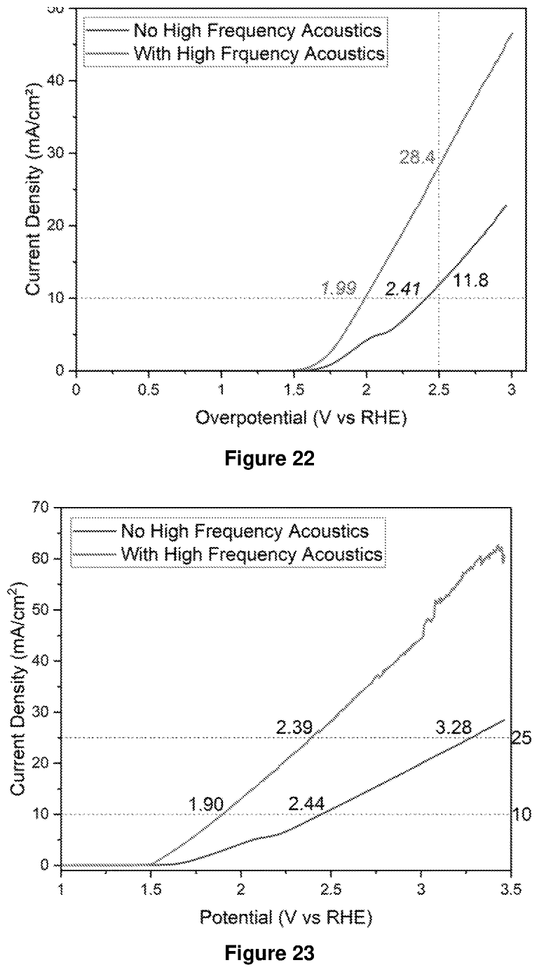

FIG. 22 shows linear sweep voltammograms (LSV) obtained with the nickel anode and alkaline electrolyte (flow rate 10 mL/min), both under silent conditions and under acoustic stimulation. The current density corresponds to the rate of oxygen production via the OER. The overpotential required to produce a current density of 10 mA/cm² was reduced from 2.41 V to 1.99 V (vs RHE) under high frequency acoustic stimulation, a reduction of 420 mV. At the same overpotential of 2.5 V vs RHE, the current density increased from 11.8 to 28.4 mA/cm² under high frequency acoustic stimulation (2.4 fold increase).

FIG. 22 shows LSVs obtained with the stainless steel anode and neutral electrolyte (flow rate 10 mL/min), both under silent conditions and under acoustic stimulation. The overpotential required to produce a current density of 10 mA/cm² was reduced from 2.44 V to 1.90 V (vs RHE) under high frequency acoustic stimulation, a reduction of 540 mV. The overpotential required to produce a current density of 25 mA/cm² was reduced from 3.28 V to 2.39 V (vs RHE) under high frequency acoustic stimulation, a reduction of 890 mV.

### Example 12. Flow Cell

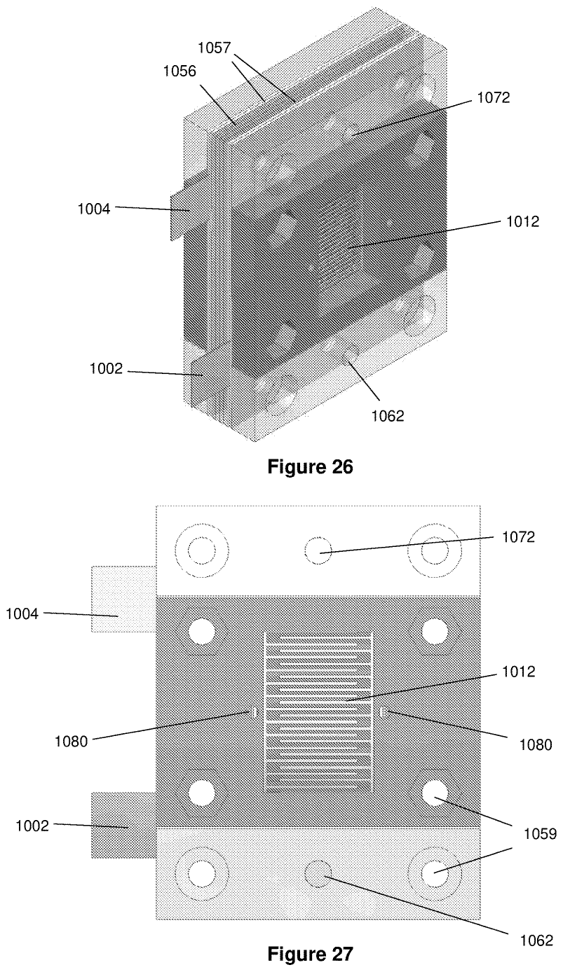

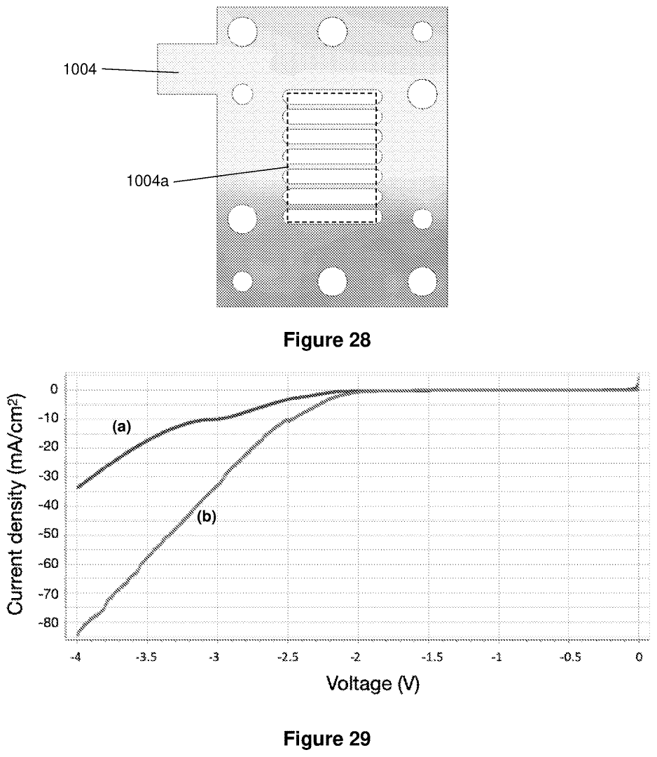

A flow cell for electrolysis of water was fabricated according to the design of cell 1000 described herein with reference to FIG. 24. The specific configuration is shown in FIG. 26, FIG. 27 and FIG. 28, showing catholyte inlet 1062, catholyte and H₂ outlet 1072, cathode-stimulating piezoelectric transducer 1012 (comprising piezoelectric substrate and interdigitated electrodes, and configured to propagate high frequency SRBW's at 7 MHz), electrical contacts 1080 for the transducer, stainless steel cathode 1002 (protruding electrical contact thereof indicated), stainless steel anode 1004 (protruding electrical contact thereof indicated). The cell is symmetrical, so that the anode-related features have the same configuration as the depicted cathode-related features. Membrane 1056 was a proton-permeable Nafion membrane. The electrodes were separated from the piezoelectric transducer 1012 by gaskets which maintained a separation distance of 0.5 mm, and the cell was bolted together via boltholes 1059. FIG. 28 shows anode 1004, with only the portion indicated by rectangle 1004a in contact with the anolyte. The working surface of both electrodes thus comprised a series of strips arranged in front of the piezoelectric transducer.

The electrochemical performance of the cell in water splitting reactions was performed using a neutral electrolyte (0.1 M neutral sodium phosphate (PBS) buffer), flowed at 2 mL/min (split to catholyte and anolyte). Each electrode was connected to a potentiostat (VSP-128, BioLogic, Seyssinet-pariset, France). All experiments were conducted at ambient temperature (c.a. 25° C.) and the result analysed using EC-Labs® software (v11.25, BioLogic, Seyssinet-pariset, France), as described in Example 5.

FIG. 29 shows linear sweep voltammograms (LSV) obtained under (a) silent conditions and (b) under acoustic stimulation at 40 dBm (7 MHz), with the acoustics applied to both electrodes. The increase in current density, and thus H₂ production rate, as a result of the acoustic stimulation is evident.

Those skilled in the art will appreciate that the invention described herein is susceptible to variations and modifications other than those specifically described. It is understood that the invention includes all such variations and modifications which fall within the spirit and scope of the present invention.

1. An electrolytic cell, comprising:
a working electrode;
a counter electrode;
a liquid electrolyte in contact with a working surface of the working electrode;
an acoustically transmissive substrate comprising at least a piezoelectric substrate portion;
one or more conductive electrodes coupled to the piezoelectric substrate portion and configured to propagate a high frequency acoustic wave having a frequency of at least 1 MHz across the acoustically transmissive substrate when electrically actuated; and
one or more power supplies configured (i) to apply a potential between the working electrode and the counter electrode sufficient to electrolytically react a species in the liquid electrolyte, thereby producing an electrolytic reaction product proximate the working electrode, and (ii) to electrically actuate the one or more conductive electrodes,
wherein the working electrode is either located on the acoustically transmissive substrate or spaced apart from the acoustically transmissive substrate by the liquid electrolyte, and
wherein propagation of the high frequency acoustic wave across the acoustically transmissive substrate in operation of the electrolytic cell stimulates the liquid electrolyte, thereby increasing the production efficiency of the electrolytic reaction product.

2. The electrolytic cell according to claim 1, wherein the working electrode is located on the acoustically transmissive substrate.

3. (canceled)

4. The electrolytic cell according to claim 1, wherein the working electrode is spaced apart from the acoustically transmissive substrate by a distance through the liquid electrolyte of no more than 30 mm.

5. The electrolytic cell according to claim 1, wherein the high frequency acoustic wave has a frequency of at least 3 MHz.

6. The electrolytic cell according to claim 1, wherein the high frequency acoustic wave comprises a wave form selected from the group consisting of a surface acoustic wave (SAW), a surface reflected bulk wave (SRBW), and a Lamb wave.

7. The electrolytic cell according to claim 1, wherein h/λ is greater than ⅓, where h is the thickness of the piezoelectric substrate portion and λ is the acoustic wavelength of the high frequency acoustic wave when propagating across the piezoelectric substrate portion.

8. (canceled)

9. (canceled)

10. (canceled)

11. (canceled)

12. The electrolytic cell according to claim 1, wherein the piezoelectric substrate portion is configured as a plate and the high frequency acoustic wave propagates in the plane of the plate, thereby oscillating at least one surface of the plate.

13. (canceled)

14. The electrolytic cell according to claim 1, wherein the one or more conductive electrodes comprises a pair of interdigitated electrodes.

15. (canceled)

16. (canceled)

17. The electrolytic cell according to claim 1, wherein the liquid electrolyte is an aqueous electrolyte, and the electrolytic reaction product is hydrogen (H₂) or oxygen (O₂).

18. (canceled)

19. (canceled)

20. A method of electrolysis, comprising:
contacting a liquid electrolyte with a working surface of a working electrode;
propagating a high frequency acoustic wave having a frequency of at least 1 MHz across an acoustically transmissive substrate, wherein the working electrode is either located on the acoustically transmissive substrate or spaced apart from the acoustically transmissive substrate by the liquid electrolyte; and
applying a potential between the working electrode and a counter electrode sufficient to electrolytically react a species in the liquid electrolyte, thereby producing an electrolytic reaction product proximate the working electrode,
wherein propagation of the high frequency acoustic wave across the acoustically transmissive substrate stimulates the liquid electrolyte, thereby increasing the production efficiency of the electrolytic reaction product.

21. The method according to claim 20, wherein the working electrode is located on the acoustically transmissive substrate.

22. The method according to claim 20, wherein the working electrode is spaced apart from the acoustically transmissive substrate by a distance through the liquid electrolyte of no more than 30 mm.

23. (canceled)

24. The method according to claim 20, wherein the electrolytic reaction product is H₂ and the potential at the working electrode is no greater than (more negative than) −1V vs RHE.

25. The method according to claim 20, wherein the liquid electrolyte is an aqueous electrolyte having a pH of between 5 and 9.

26. The method according to claim 20, wherein the high frequency acoustic wave has a frequency of at least 3 MHz.

27. The method according to claim 20, wherein the high frequency acoustic wave comprises a wave form selected from the group consisting of a surface acoustic wave (SAW), a surface reflected bulk wave (SRBW) and a Lamb wave.

28. The method according to claim 20, wherein the power input to propagate the high frequency acoustic wave across the acoustically transmissive substrate, normalised to the surface area of the acoustically transmissive substrate, is less than 20 W/cm².

29. The method according to claim 20, wherein propagating the high frequency acoustic wave across the acoustically transmissive substrate comprises electrically actuating one or more conductive electrodes coupled to a piezoelectric substrate portion of the acoustically transmissive substrate.

30. (canceled)

31. The method according to claim 29, wherein h/λ is greater than ⅓, where h is the thickness of the piezoelectric substrate portion and λ is the acoustic wavelength of the high frequency acoustic wave when propagating across the piezoelectric substrate portion.

32. (canceled)

33. (canceled)

34. (canceled)

35. The method according to claim 29, wherein the piezoelectric substrate portion is configured as a plate and the high frequency acoustic wave propagates in the plane of the plate, thereby oscillating at least one surface of the plate.

36. (canceled)

37. (canceled)

38. (canceled)
